(19) United States
(12) Patent Application Publication
(10) Pub. No.: US 2013/0121510 A1
(43) Pub. Date: May 16, 2013

(54) CONTROLLING TERMINAL APPARATUS, CONTROL METHOD AND PROGRAM

(71) Applicant: SONY CORPORATION, TOKYO (JP)

(72) Inventors: Naoki YUASA, Chiba (JP); Fumihiko Nishio, Saitama (JP); Kazuma Takahashi, Chiba (JP); Keishi Tsuchiya, Kanagawa (JP)

(73) Assignee: SONY CORPORATION, TOKYO (JP)

(21) Appl. No.: 13/670,990

(22) Filed: Nov. 7, 2012

(30) Foreign Application Priority Data
Nov. 14, 2011 (JP) 2011-248247

(51) Int. Cl. H03G 3/02

(52) U.S. Cl. CPC H03G 3/02
USPC 381/109

(57) ABSTRACT

Disclosed herein is a controlling terminal apparatus including: a transmission section transmitting and outputting a control signal to a plurality of sound outputting apparatus; a display section; an operation detection section detecting an operation for the displayed substance of the display section; and a control section controlling the display section to display, for each of the sound outputting apparatus, an individual sound volume setting region and a master sound volume setting region, the control section changing, when an operation for the master sound volume setting region is detected by the operation detection section, the sound volume setting of each of the individual sound volume setting regions using a value with respect to an operable amount of each of the individual sound volume setting regions, generating control signals indicative of the new sound volume settings, and controlling the transmission section to transmit and output the control signals.

### BACKGROUND

The present disclosure relates to a controlling terminal apparatus, a control method and a program which can control a sound volume setting state of a plurality of sound outputting apparatus.

For example, a mixer apparatus is known to which multiple channel audio signals are inputted and which controls the sound volume level of the audio signals after mixed while a sound volume balance between channels is maintained by a master fader as disclosed in Japanese Patent Laid-Open No. 2005-80265 or Japanese Patent Laid-Open No. 2006-339709.

### SUMMARY

However, different from an apparatus which controls the level of audio signals of different channels after mixed like a mixer, an apparatus which appropriately controls the sound volume of individual sound outputting apparatus has not been developed.

For example, in a home network system, sound outputting apparatus disposed in different rooms receive music content or the like distributed from a single source apparatus and individually reproduce and output the music content. This can create a situation in which the same music is played in the different rooms.

With such a system as just described, the following situations may be assumed:

It is desired to control the sound volumes of the individual sound outputting apparatus independently of each other;

It is desired to control the sound volumes of the sound outputting apparatus collectively without losing the sound volume balance between the sound outputting apparatus; and

It is desired to collectively control the sound volumes of the sound outputting apparatus even if the sound volume balance between the sound volume outputting apparatus is lost.

Therefore, it is desirable to provide a controlling terminal apparatus and a control method and a program which can carry out sound volume control of a plurality of sound outputting apparatus readily, for example, in such situations as described above.

Particularly, for example, in a home network system, it is desired to make it possible to carry out sound volume control of a plurality of sound outputting apparatus appropriately in a situation in which a sound mixing console (mixer) which is popularly used in PA (public address) application or the like does not exist.

According to an embodiment of the present disclosure, there is provided a controlling terminal apparatus including: a transmission section configured to transmit and output a control signal to a plurality of sound outputting apparatus; a display section; an operation detection section configured to detect an operation for the displayed substance of the display section; and a control section configured to control the display section to display, for each of the sound outputting apparatus, an individual sound volume setting region showing a sound volume setting and including an operation element which can be operated to vary the sound volume setting, and a master sound volume setting region including an operation element which can be operated to vary the sound volume settings of the sound outputting apparatus at the same time, the control section changing, when an operation for the master sound volume setting region is detected by the operation detection section, the sound volume setting of each of the individual sound volume setting regions using a value, which has a ratio equal to the ratio of the detected operation amount to an operable amount of the master sound volume setting region upon the operation, with respect to an operable amount of each of the individual sound volume setting regions, generating control signals indicative of the new sound volume settings, and controlling the transmission section to transmit the control signals.

According to another embodiment of the present disclosure, there is provided a control method performed by a controlling terminal apparatus which includes a transmission section configured to transmit and output a control signal to a plurality of sound outputting apparatus, a display section, and an operation detection section configured to detect an operation for the displayed substance of the display section, the method including: controlling the display section to display, for each of the sound outputting apparatus, an individual sound volume setting region showing a sound volume setting and including an operation element which can be operated to vary the sound volume setting, and a master sound volume setting region including an operation element which can be operated to vary the sound volume settings of the sound outputting apparatus at the same time; changing, when an operation for the master sound volume setting region is detected by the operation detection section, the sound volume setting of each of the individual sound volume setting regions using a value, which has a ratio equal to the ratio of the detected operation amount to an operable amount of the master sound volume setting region upon the operation, with respect to an operable amount of each of the individual sound volume setting regions; and generating control signals indicative of the changed new sound volume settings and controlling the transmission section to transmit the control signals.

According to a further embodiment of the present disclosure, there is provided a program which causes an arithmetic operation processing apparatus of a controlling terminal apparatus which includes a transmission section configured to transmit and output a control signal to a plurality of sound outputting apparatus, a display section, and an operation detection section configured to detect an operation for the displayed substance of the display section, to execute processing of: controlling the display section to display, for each of the sound outputting apparatus, an individual sound volume setting region showing a sound volume setting and including an operation element which can be operated to vary the sound volume setting, and a master sound volume setting region including an operation element which can be operated to vary the sound volume settings of the sound outputting apparatus at the same time; changing, when an operation for the master sound volume setting region is detected by the operation detection section, the sound volume setting of each of the individual sound volume setting regions using a value, which has a ratio equal to the ratio of the detected operation amount to an operable amount of the master sound volume setting region upon the operation, with respect to an operable amount of each of the individual sound volume setting regions; and generating control signals indicative of the changed new sound volume settings and controlling the transmission section to transmit the control signals.

In the technology of the present disclosure, a plurality of individual sound volume setting regions individually corresponding to a plurality of sound outputting apparatus disposed, for example, on a network and one master sound volume setting region are displayed on the display section of the controlling terminal apparatus.

The user can carry out an operation of increasing or decreasing the sound volume of each of the sound outputting apparatus by an operation for the individual sound volume setting regions. Further, the user can carry out an operation of increasing or decreasing the sound volume of plural ones of the sound outputting apparatus in a state in which the sound volume balance between or among the sound outputting apparatus is maintained or is not maintained by an operation for the master sound volume setting region.

Particularly, if an operation for the master sound volume setting region is detected, then the sound volume setting of each of the individual sound volume setting regions is changed, namely, the sound volume is increased or decreased, using a value, which has a ratio equal to the ratio of the detected operation amount to the operable amount of the master sound volume setting region upon the operation, with respect to an operable amount of each of the individual sound volume setting regions. When it is desired to collectively operate the sound volumes even if the sound volume balance is lost, sound volume control for the sound outputting apparatus can be executed smoothly by such control.

With the present disclosure, individual sound volume operation and collective sound volume operation for a plurality of sound outputting apparatus on a network can be executed readily using the controlling terminal apparatus. Particularly with regard to the collective sound volume operation, sound volume adjustment can be carried out smoothly by an operation of the master sound volume setting region.

### BRIEF DESCRIPTION OF THE DRAWINGS

FIG. 1 is a block diagram showing a basic configuration of a system according to an embodiment of the present disclosure;

FIG. 2 is a schematic view of a home network system according to the embodiment;

FIG. 3 is a block diagram of a reproduction apparatus shown in FIG. 2;

FIG. 4 is a block diagram of a network speaker shown in FIG. 2;

FIG. 5 is a block diagram of a remote controller shown in FIG. 2;

FIG. 6 is a schematic view of the remote controller of FIG. 5;

FIGS. 7A and 7B are schematic views showing examples of a sound volume operation display image on the remote controller of FIG. 5;

FIGS. 8A and 8B are schematic views showing display images displayed in response to an operation of a master sound volume setting region on the remote controller;

FIGS. 9A, 9B, 9C and 9D are schematic views showing examples of a display image of a sound volume balance maintaining range on the remote controller;

FIGS. 10A, 10B, 10C and 10D are schematic views showing different examples of a display image of a sound volume balance maintaining range on the remote controller;

FIGS. 11A and 11B are schematic views illustrating a variation of a sound volume balance maintaining range and central display of a knob displayed on the remote controller;

FIGS. 12A and 12B are schematic views illustrating a knob locking operation on the remote controller;

FIGS. 13A and 13B are schematic views of a muting operation on the remote controller;

FIGS. 14A, 14B, 15A, 15B and 16A, 16B are schematic views of operations of a sound volume balance non-maintaining state on the remote controller;

FIGS. 17A and 17B are schematic views illustrating states of different knob operation in the sound volume balance non-maintaining state on the remote controller;

FIGS. 18 to 22 are flow charts illustrating an operation dealing process on the remote controller; and

FIGS. 23A and 23B are schematic views illustrating different operation of the remote controller.

### DETAILED DESCRIPTION OF THE PREFERRED EMBODIMENT

In the following, an embodiment is described in the following order:

### <1. Basic Configuration>

### <2. Home Network System>

### <3. Apparatus Configuration>

3-1: Reproduction Apparatus

3-2: Network Speaker

3-3: Remote Controller

### <4. Operation Using Sound Volume Operation Display (Sound Volume Balance Maintaining State)>

### <5. Knob Locking Operation>

### <6. Muting Operation>

### <7. Operation Using Sound Volume Operation Display (Sound Volume Balance Non-Maintaining State)>

### <8. Example of a Process>

### <9. Modifications and Program>

### <1. Basic Configuration>

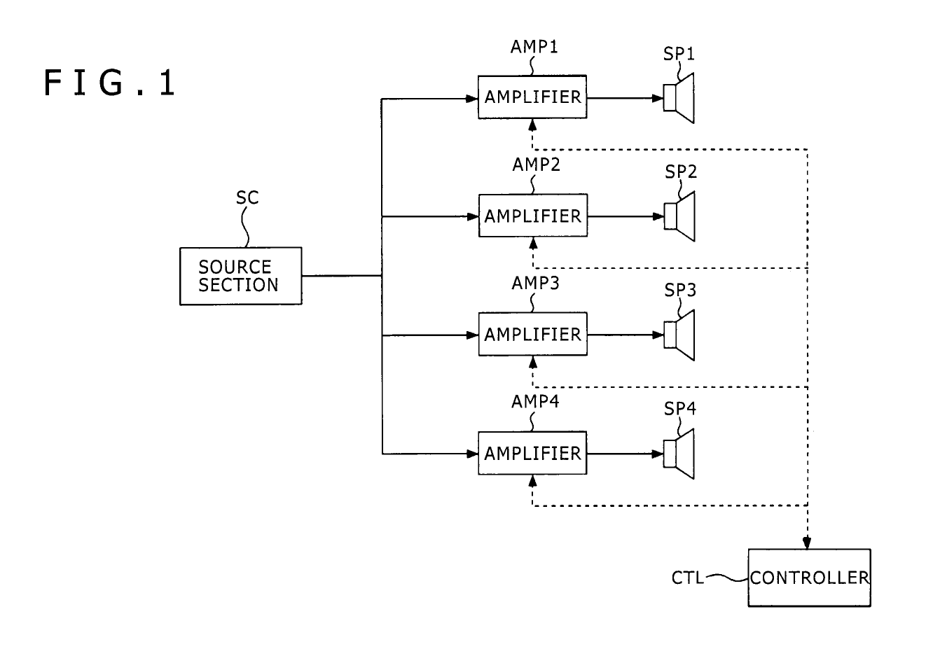

FIG. 1 shows an example of a basic system configuration according to an embodiment to which the technology of the present disclosure is used.

Here, an apparatus which outputs music content and so forth is shown as a source section SC. Music content and so forth outputted from the source section SC are supplied to amplifiers AMP1 to AMP4.

The amplifiers AMP1 to AMP4 output received music content as sound from speakers SP1 to SP4, respectively.

A controller CTL carries out sound volume control of the amplifiers AMP1 to AMP4. The user can operate the controller CTL to carry out sound volume operation individually for the amplifiers AMP1 to AMP4 or collectively for the amplifiers AMP1 to AMP4.

Particularly in the case of collective sound volume operation, the sound volume setting of each of the amplifiers AMP1 to AMP4 can be changed while the sound volume balance among the amplifiers AMP1 to AMP4 are maintained or even if the sound volume balance is lost.

For example, although an example of a home network system, namely, a network in a home, is hereinafter described, the amplifiers AMP1 to AMP4 shown in FIG. 1 can be considered as sound outputting apparatus of separate bodies disposed in different rooms from one another.

Among the different rooms, an optimum sound volume required for music or the like by a user differs depending upon the size of the room, performance of a speaker, the installation place, an atmospheric setting of the room and so forth.

Therefore, the amplifiers AMP1 to AMP4 are desired to be set to different sound volume conditions. In other words, the amplifiers AMP1 to AMP4 are desired to be controlled independently of each other through the controller CTL.

Further, in such a state, it is sometimes desired to collectively carry out sound volume adjustment of the amplifiers AMP1 to AMP4 while a relative sound volume balance among the amplifiers AMP1 to AMP4 is maintained (operation in a sound volume balance maintaining state).

Furthermore, it is sometimes desired to collectively carry out sound volume adjustment of the amplifiers AMP1 to AMP4 even if a relative sound volume balance among the amplifiers AMP1 to AMP4 is lost (operation in a sound volume balance non-maintaining state).

In the present embodiment, an operation technique which satisfies such requests of users as described above is provided by an apparatus which corresponds to the controller CTL in an environment in which the same music or the like is reproduced and outputted synchronously by a plurality of sound outputting apparatus.

### <2. Home Network System>

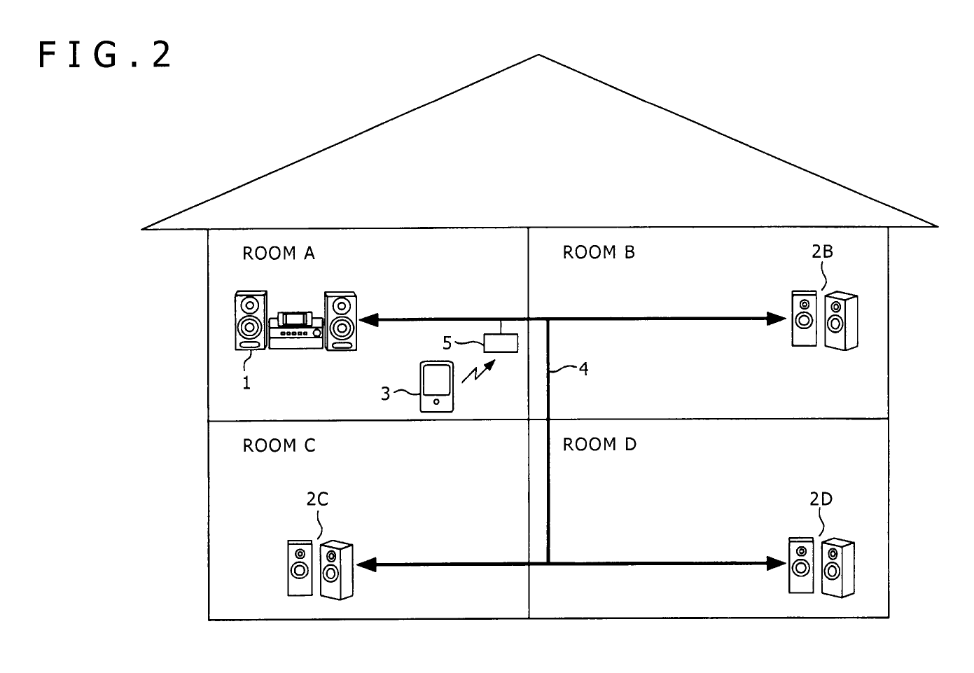

A configuration of a home network system which is an actual form of the basic configuration described hereinabove with reference to FIG. 1 is described below with reference to FIG. 2.

FIG. 2 shows an example wherein a home network system is used in rooms A, B, C and D.

Although the term “home network system” is used, naturally the place in which the system of the present example is used is not limited to a “home.” The system of the present embodiment can be used, for example, also in a company, a school, a public facility and so forth. Further, the “rooms” may not be those in the same building, but outdoor sites such as a garden, a garage or a storehouse on a premise or the inside of a different building may be considered a “room” here. In short, in the case of the present example, one electronic apparatus in a certain room distributes the same music content or video content to the other electronic apparatus which serve as servers so that the content can be enjoyed in the individual “rooms.” However, the “rooms” to which the same content is distributed may be various rooms. Further, it is appropriate to consider the system of the present example as a system which is not intended for distribution over such a wide range as is executed by a public network such as the Internet but is intended for distribution within a somewhat narrow range.

It is to be noted that, in the following description of the embodiment, the system is described as a system which distributes music content.

In the home network system of the present embodiment, various electronic apparatus disposed in different rooms are configured for mutual communication through a communication network 4.

The home network system shown in FIG. 2 is shown as an example of a comparatively simple system.

In the example of FIG. 2, a reproduction apparatus 1 is disposed in the room A.

A network speaker 2B is disposed in the room B.

A network speaker 2C is disposed in the room C.

A network speaker 2D is disposed in the room D.

Further, in the room A, a remote controller 3 which includes a display function and a touch panel function is disposed.

For example, the remote controller 3 can communicate with various apparatus on the network 4 through an access point 5 which can communicate by wireless or wire communication to transmit a control command and acquire information of the various apparatus such as, for example, sound volume setting information of the apparatus.

The user can use the remote controller 3 to carry out sound volume adjustment of the apparatus in the rooms A to D.

It is to be noted that the installation position of the access point 5 is not limited to the room A. Further, if the communication range between the access point 5 and the remote controller 3 is wide, then also it is possible to operate the various apparatus using the remote controller 3 from any room. Further, the access point 5 may be disposed in each of the rooms.

Further, the remote controller 3 may be formed as an inputting apparatus for the reproduction apparatus 1 and as an apparatus which can transmit a control command to the reproduction apparatus 1 and transmit a control command to the other apparatus on the network 4 through the reproduction apparatus 1.

The reproduction apparatus 1 includes a reproduction section, a speaker section and so forth, for example, for music content and can carry out reproduction of music and so forth by itself.

The reproduction apparatus 1 can reproduce content data from a hard disc driver (HDD), a flash memory, an exchange type optical disc player which accommodates a plurality of optical discs such as, for example, a CD (Compact Disc), a DVD (Digital Versatile Disc) or a BD (Blu-ray Disc (registered trademark)), or a like device.

Music content data reproduced by the reproduction apparatus 1 can be outputted from a built-in speaker, a speaker connected to the reproduction apparatus 1 or the like.

Meanwhile, the reproduction apparatus 1 is communicatable with the individual apparatus through the network 4 such that it can function as a server apparatus. The reproduction apparatus 1 as a server apparatus can distribute reproduced music content data to the other apparatus on the network 4, namely to the network speakers 2B, 2C and 2D.

While the network speakers 2B, 2C and 2D are sound outputting apparatus each including an amplifier and a speaker section, they particularly include a network communication function and can function as a client apparatus on the system.

For example, if the reproduction apparatus 1 serves as a server on the system, then the network speakers 2B, 2C and 2D can receive music content distributed from the reproduction apparatus 1 and output the music content as music.

The network 4 is configured from a wire or wireless transmission line along which communication, for example, in a home can be carried out.

For example, in the case where the network 4 is a wire transmission line, a lamp line, a television RF (Radio Frequency) cable, a DLNA (Digital Living Network Alliance), an HDMI (High Definition Multimedia Interface) and so forth may be applicable. On the other hand, in the case where the network 4 is wireless transmission line, a wireless LAN (Local Area Network, IEEE802.11x (=a, b, g, n, . . . )), the Bluetooth communication system, a communication system which uses the 2.4 GHz band and so forth are available.

In the present embodiment, the home network system is described assuming a situation in which such system operation that the reproduction apparatus 1 serves as a server and synchronously distributes music content to the other client apparatus, namely, to the network speakers 2B, 2C and 2D so that the music content is reproduced simultaneously by the client apparatus is carried out. The system operation is operation in a party mode of the home network.

Here, it is assumed that each of the apparatus in the home network system, namely the reproduction apparatus 1 and the network speakers 2B, 2C and 2D, recognizes in which room any other apparatus is installed. For example, the reproduction apparatus 1 recognizes that the network speaker 2B is installed in the room B.

This is possible by the user setting, when it installs the individual apparatus, a room (zone) of each of the apparatus.

Further, information regarding what apparatus are disposed on the network 4 is registered in advance also in the remote controller 3 with a GUI (Graphic User Interface) which can be operated on a touch panel.

Here, the home network system and the basic configuration of FIG. 1 have the following correspondence.

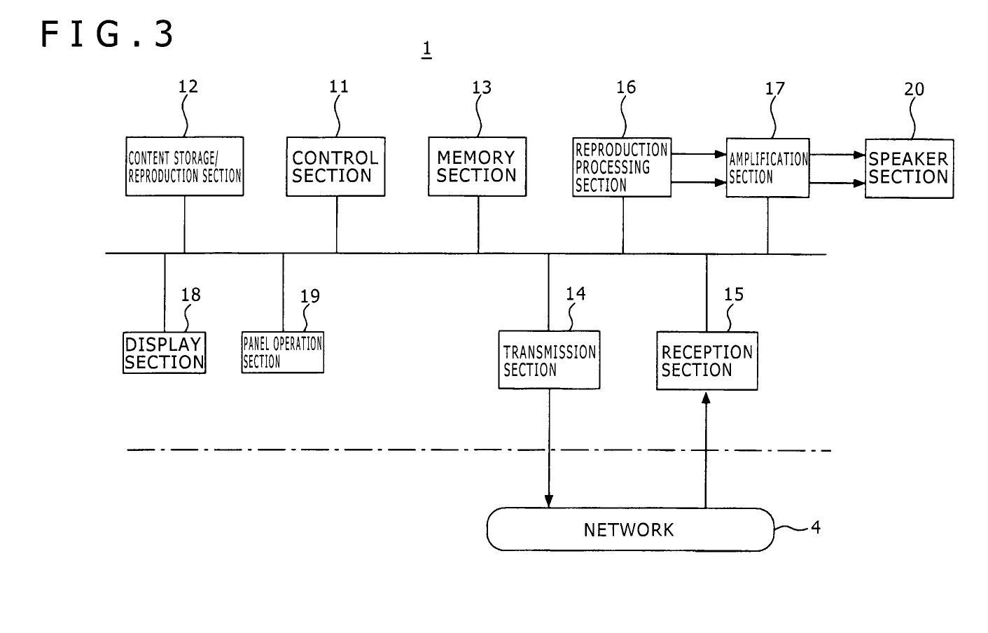

For example, the reproduction apparatus 1 which serves as a server corresponds to the source section SC. Further, the amplifier AMP1 and the speaker SP1 may be considered sound outputting systems of the reproduction apparatus 1, which are a reproduction processing section 16, an amplification section 17 and a speaker section 20 hereinafter described with reference to FIG. 3.

The amplifier AMP2 and the speaker SP2 can be considered the network speaker 2B.

The amplifier AMP3 and the speaker SP3 can be considered the network speaker 2C.

The amplifier AMP4 and the speaker SP4 can be considered the network speaker 2D.

The remote controller 3 corresponds to the controller CTL.

Naturally, the home network system may have various configurations, and for example, a plurality of reproduction apparatus each of which can function as a server and a client apparatus may be installed. Or, an apparatus for exclusive use as a server may be provided. Naturally, more various apparatus may be installed in a greater number of rooms.

Accordingly, naturally the configurations shown in FIGS. 1 and 2 are mere examples.

Here, the remote controller 3 is an example of a controlling terminal apparatus.

The remote controller 3 is an apparatus which can control the output sound volume of a plurality of sound outputting apparatus in response to a user operation. While the sound outputting apparatus of a controlling target are the amplifiers AMP1 to AMP4 of FIG. 1, in FIG. 2, they are the reproduction apparatus 1 and the network speakers 2B, 2C and 2D.

If the remote controller 3 is used, then the user can execute operations corresponding to the following cases when the same music content or the like is synchronously reproduced and outputted by the sound outputting apparatus, namely, the reproduction apparatus 1 and the network speakers 2B, 2C and 2D:

It is desired to individually control the sound volumes of the reproduction apparatus 1 and the network speakers 2B, 2C and 2D;

It is desired to collectively control the sound volumes of the reproduction apparatus 1 and the network speakers 2B, 2C and 2D without losing the sound volume balance among the apparatus;

It is desired to collectively control the sound volumes of the reproduction apparatus 1 and the network speakers 2B, 2C and 2D even if the sound volume balance is lost;

It is desired to temporarily suppress or disable sound volume control of a particular one or ones of the reproduction apparatus 1 and the network speakers 2B, 2C and 2D;

It is desired to temporarily place a particular one or ones of the reproduction apparatus 1 and the network speakers 2B, 2C and 2D into an output stopping or muting state while the sound volume setting is kept; and

It is desired to collectively cancel the mute state of those of the reproduction apparatus 1 and the network speakers 2B, 2C and 2D which are in a mute state.

### <3. Apparatus Configuration>

### 3-1. Reproduction Apparatus

An example of a configuration of the individual apparatus connected to the network 4 is described. First, an example of a configuration of the reproduction apparatus 1 is described with reference to FIG. 3.

The reproduction apparatus 1 includes a control section 11, a content storage/reproduction section 12, a memory section 13, a transmission section 14, a reception section 15, a reproduction processing section 16, an amplification section 17, a display section 18, a panel operation section 19 and a speaker section 20.

The control section 11 is configured from a microcomputer which includes a CPU (Central Processing Unit), a ROM (Read Only Memory), a RAM (Random Access Memory) and so forth.

In the ROM in the control section 11, for example, various kinds of setting information for a reproduction operation, a network communication operation and so forth and other information are stored in addition to programs to be executed by the CPU. The RAM is used as a main storage apparatus section for the CPU.

The control section 11 controls the entire reproduction apparatus 1 such that the reproduction apparatus 1 executes necessary operation in all of a case in which the reproduction apparatus 1 by itself carries out a reproduction operation, another case in which it functions as a server apparatus and a further case in which it functions as a client apparatus.

For example, the control section 11 carries out reproduction operation control by the content storage/reproduction section 12, communication operation by the transmission section 14 and the reception section 15, and so forth.

The memory section 13 collectively indicates a storage section such as a RAM, a ROM and a flash memory. The memory section 13 may be used as a working area for processing of the control section 11 or as a storage area for a program. Further, the memory section 13 is used also to store various kinds of setting information, parameters and so forth for a distribution operation.

The memory section 13 is used also as a transmission buffer for content data reproduced by the content storage/reproduction section 12 for distribution when the reproduction apparatus 1 functions as a server apparatus and further used as a reception buffer of content data when the reproduction apparatus 1 functions as a client apparatus.

The content storage/reproduction section 12 is an apparatus section which can reproduce various content data. The content data are stored, for example, in a hard disc, a flash memory or an optical disc. The content storage/reproduction section 12 reproduces content data from the storage media in accordance with an instruction of the control section 11. Accordingly, the content storage/reproduction section 12 is implemented, for example, as a HDD, a flash memory player, an optical disc player, an exchange-type optical disc player or the like.

The transmission section 14 and the reception section 15 function as a communication section with a different apparatus through the network 4.

The transmission section 14 carries out, when the reproduction apparatus 1 functions as a server apparatus, predetermined encoding of content data reproduced principally by the content storage/reproduction section 12 under the control of the control section 11. The transmission section 14 further carries out network transmission, in other words, distribution, of the encoded content data to the network speakers 2B, 2C and 2D serving as client apparatus.

The reception section 15 receives information transmitted thereto from a different apparatus on the network 4. If a control command from the remote controller 3 is received, then the reception section 15 decodes the signal of the control command and transmits the substance of reception information to the control section 11.

Further, although the example of FIG. 2 does not include another server apparatus, another server apparatus is sometimes connected and the reproduction apparatus 1 may function as a client apparatus. In this instance, the reception section 15 receives a signal transmitted from the server apparatus, for example, content data distributed thereto or various other instruction signals. Then, the reception section 15 decodes the received signal. Upon reception of content data distributed thereto, the reception section 15 transfers content data, namely, stream data, obtained by a decoding process in accordance with a communication method carried out for the received data, to the memory section 13 under the control of the control section 11 so as to be buffered by the memory section 13.

In order to carry out, for example, such processes as described above, the transmission section 14 and the reception section 15 carry out encoding, decoding and transmission and reception processes in accordance with the communication method by wire or wireless communication through the network 4.

The reproduction processing section 16 carries out a process for reproduction outputting for content data reproduced by the content storage/reproduction section 12 and content data received through distribution.

When music content or the like is to be synchronously reproduced by the sound outputting apparatus in the system of FIG. 2, the control section 11 causes content data reproduced by the content storage/reproduction section 12 to be distributed from the transmission section 14 to the network speakers 2B, 2C and 2D. However, the control section 11 causes also the reproduction apparatus 1 to reproduce and output the content data. In this instance, the control section 11 causes the content data reproduced by the content storage/reproduction section 12 to be transferred to the reproduction processing section 16 so as to cause the reproduction processing section 16 to execute a reproduction outputting process.

The reproduction processing section 16 carries out processes for outputting for the content data, for example, decoding and error correction relating to a compression process and supplies a resulting audio signal such as, for example, stereo audio signals for L and R channels, to the amplification section 17.

The amplification section 17 carries out sound volume control, equalizing and D/A (digital-to-analog) conversion processes and so forth and supplies a resulting audio signal to the speaker section 20 so as to execute outputting of, for example, music.

The control section 11 carries out sound volume control in the amplification section 17, for example, in accordance with a control command from the remote controller 3.

It is to be noted that, while, in the present example, only sound outputting systems by the amplification section 17 and the speaker section 20 are shown as outputting devices, also synchronous reproduction of video content may be carried out in the home network system. In this instance, for example, a monitor display apparatus and so forth may be provided as outputting devices.

Further, although the speaker section 20, monitor display apparatus and so forth as the outputting devices may be provided integrally in a housing of the reproduction apparatus 1, naturally they may be configured otherwise as separate apparatus from one another.

The display section 18 is a small-sized display panel provided, for example, on the housing of the reproduction apparatus 1 and carries out operation state display, menu display, icon display, equalizer display, title display, message display and so forth under the control of the control section 11. The display section 18 is configured, for example, from a liquid crystal panel or an organic EL (electroluminescence) panel.

It is to be noted that also it is possible to achieve such displays as described above using a monitor display apparatus connected as an outputting device. In this instance, the display section 18 may not be provided.

The panel operation section 19 collectively represents operation elements such as, for example, operation keys and a jog dial provided on the housing of the reproduction apparatus 1. It is to be noted that, if the display section 18 or a monitor display apparatus connected as an outputting device allows touch panel inputting, then also the touch panel mechanism is a component of the panel operation section 19.

Further, though not shown, in the case where a remote controller for exclusive use is provided for the reproduction apparatus 1, also a reception section for a control signal from the remote controller such as, for example, an infrared reception section, a radio wave reception section or a wire-connected reception section is a component of the panel operation section 19.

The user can carry out various kinds of operation inputting by an operation of operation elements of the panel operation section 19, a touch panel operation for menu display or icon display on the display section 18 or the monitor display apparatus or an operation using a remote controller for exclusive use.

The control section 11 carries out operation control, a setting process and so forth in the reproduction apparatus 1 in response to an operation input of the user or carries out a signal transmission process from the transmission section 14 to a different apparatus.

In addition to such user operations, in the present embodiment, the user can carry out an output sound volume setting operation of the reproduction apparatus 1 through the remote controller 3.

It is to be noted that the configuration example of the reproduction apparatus 1 described above is a mere example.

### 3-2. Network Speaker

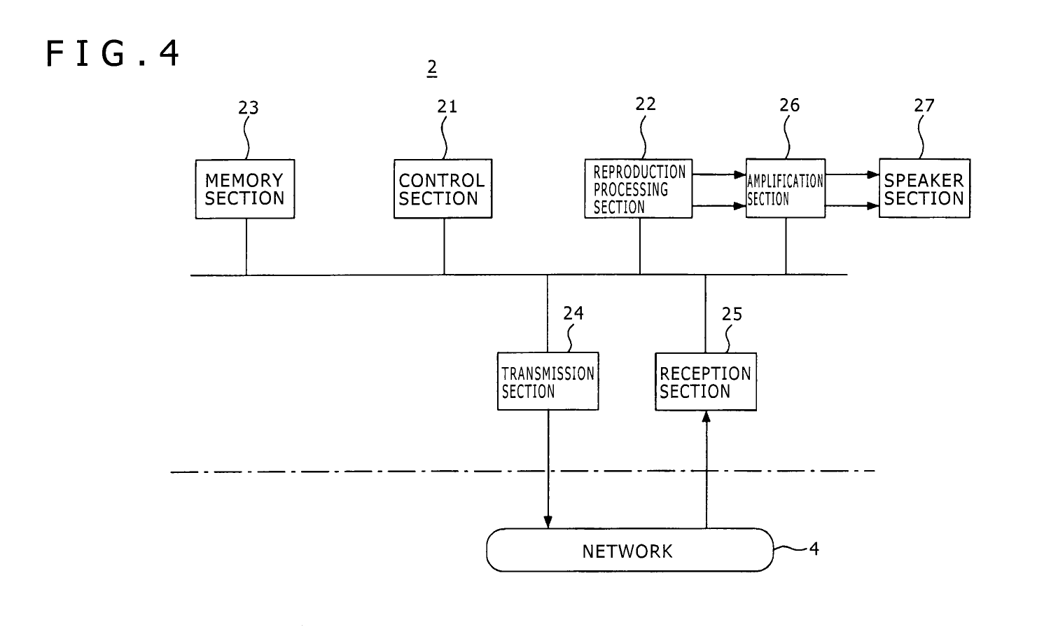

Now, an example of a configuration of a network speaker 2 (2B, 2C or 2D) is described with reference to FIG. 4.

The network speaker 2 includes a control section 21, a reproduction processing section 22, a memory section 23, a transmission section 24, a reception section 25, an amplification section 26 and a speaker section 27.

The control section 21 is configured from a microcomputer including a CPU, a ROM, a RAM and so forth.

The ROM in the control section 21 stores therein, for example, various kinds of setting information for a reproduction operation of distribution content, a communication operation with a different apparatus and so forth in addition to programs to be executed by the CPU. The RAM is used as a main storage apparatus section for the CPU.

The control section 21 controls operation of the network speaker 2 in order that the network speaker 2 functions as a client apparatus. In particular, the control section 21 carries out reception control of content data and a control command distributed thereto, a process in accordance with the control command and so forth.

The memory section 23 collectively represents storage sections such as a RAM, a ROM and a flash memory. The memory section 23 may be used as a working area for processing by the control section 21 or as a storage area for programs. The memory section 23 is used also to store various kinds of setting information, parameters and so forth for a reproduction operation or a communication operation.

Further, the memory section 23 is used also as a buffer memory for received content data.

The transmission section 24 and the reception section 25 function as a communication section with the other apparatus through the network 4.

The reception section 25 receives a signal transmitted thereto from the reproduction apparatus 1, for example, content data, a control command and so forth distributed thereto. Then, the reception section 25 decodes the received signal. Upon reception of distributed content data, the reception section 25 transfers the content data, namely, stream data, for which a decoding process in accordance with the communication method is carried out for the received data, for example, to the memory section 23 under the control of the control section 21 so as to be buffered by the memory section 23.

On the other hand, if a control command from the remote controller 3 is received, then the reception section 25 decodes the signal and transmits the received information contents to the control section 21.

The transmission section 24 carries out predetermined encoding for a transmission signal to a different apparatus under the control of the control section 21 and transmits and outputs the encoded signal to the network 4.

In order to carry out such processes as described above, the transmission section 24 and the reception section 25 carry out encoding, decoding and transmission and reception processes corresponding to the communication system by wire or wireless communication through the network 4.

The reproduction processing section 22 carries out a process for reproduction outputting by the speaker section 27 for the received content data. For example, while the received content data are buffered by the memory section 23, individual data which configure the buffered content data are transferred to the reproduction processing section 22 successively at predetermined timings. The reproduction processing section 22 carries out a process for outputting for the content data, for example, decoding and error correction for a compression process and supplies an audio signal, for example, stereo audio signals of the L and R channels, to the amplification section 26.

The amplification section 26 carries out sound volume control, equalizing and D/A conversion processes and so forth and supplies an audio signal to the speaker section 27 so that the speaker section 27 executes outputting of, for example, music.

Consequently, sound of the distributed music content or the like is outputted from the speaker section 27 so as to be enjoyed by the user.

The control section 21 carries out sound volume control of the amplification section 26 in response to a control command, for example, from the remote controller 3.

It is to be noted that, while the speaker section 27 may be provided integrally with the housing of the network speaker 2, it may be formed otherwise as a separate apparatus. Particularly, in the case where speakers for the L and R channels are provided as stereo speakers, usually at least speaker unit sections are configured as separate blocks.

While FIG. 4 shows a configuration example of the network speaker 2, all of the network speakers 2B, 2C and 2D need not have a configuration similar to that described above, but some other element may be provided additionally or some component of the configuration of FIG. 4 may be omitted.

### 3-3. Remote Controller

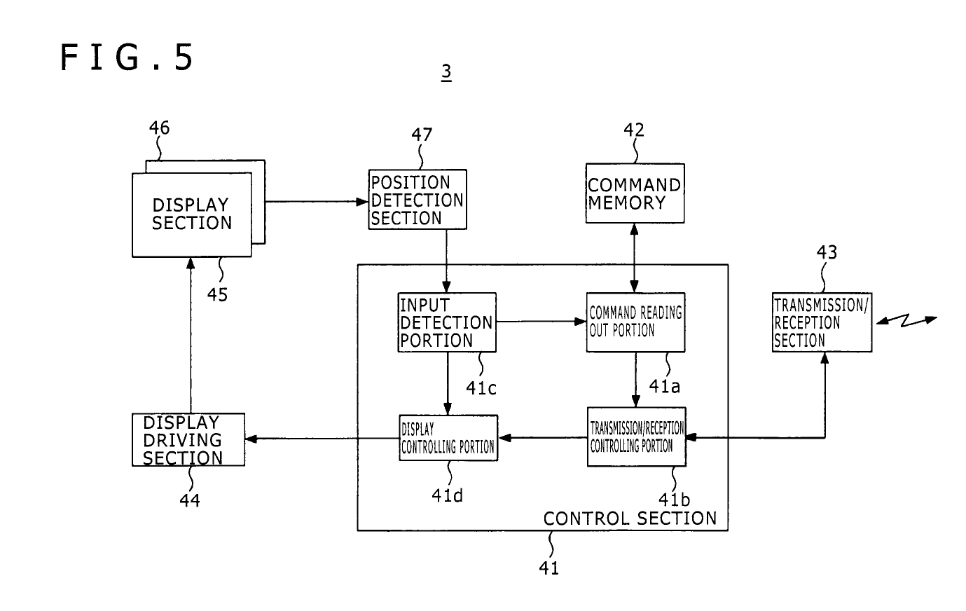

Now, an example of a configuration of the remote controller 3 is described with reference to FIG. 5.

The remote controller 3 includes a control section 41, a command memory 42, a transmission/reception section 43, a display driving section 44, a display section 45, a touch panel sensor 46, and a position detection section 47.

The control section 41 is configured from a microcomputer.

The command memory 42 is formed from a ROM, a nonvolatile memory or the like and stores various command codes.

The transmission/reception section 43 carries out modulation and transmission in accordance with a predetermined communication method for transmission of command codes. Further, the transmission/reception section 43 communicates with the apparatus on the network 4 to receive information from the apparatus. In other words, the transmission/reception section 43 functions as a transmission section and a reception section with respect to the apparatus on the network 4.

In the remote controller 3, a user operation is carried out principally by a touch panel operation. To this end, the display section 45 is provided and the touch panel sensor 46 is formed on the display face of the display section 45.

The display section 45 is, for example, a liquid crystal panel or an organic EL panel, and the touch panel sensor 46 such as a piezoelectric sensor or an electrostatic sensor is provided on the surface of the display section 45 thereby to form a touch panel.

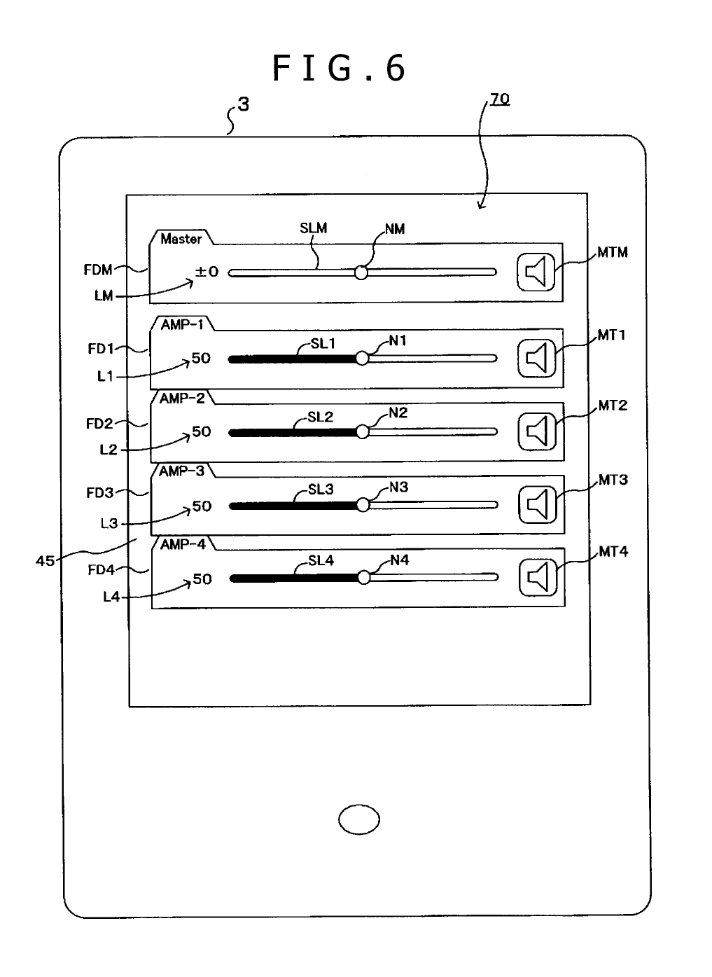

On the display section 45, for example, buttons, icons and so forth for operation are displayed to allow various kinds of operation inputting. In the present embodiment, as one of display images for operation inputting, sound volume operation display image 70 is displayed on the display section 45 such that the user can carry out operation inputting by a touching operation with the sound volume operation display image 70 as hereinafter described with reference to FIG. 6 and so forth.

In other words, the display section 45 provides an operation unit to the user using a function as a GUI (Graphical User Interface).

The display section 45 is driven to display by the display driving section 44. When the control section 41 provides display data to the display driving section 44, the display driving section 44 provides a display driving signal to the display section 45 based on the display data so as to execute predetermined screen display. For example, the display driving section 44 causes the display section 45 to display, for example, such sound volume operation display image as shown in FIG. 6, or a different display image of various operation keys and icons, an operation menu display image and so forth.

The user would carry out a touching operation in response to the substance of a displayed image. The touch panel sensor 46 transmits information of the touching operation to the position detection section 47. The position detection section 47 discriminates the position of the user operation in the form of a touching operation, namely, the X-Y coordinate positions on the display face, and transmits to the control section 41 the discriminated position as touch position information.

In the control section 41, a command reading out portion 41a, a transmission/reception controlling portion 41b, an input detection portion 41c and a display controlling portion 41d are formed as functional components implemented by a software program.

The input detection portion 41c recognizes information of a touch position from the position detection section 47 and discriminates the substance of the operation intended by the user from the touch position or a locus of the touch position.

The command reading out portion 41a reads out a command code from the command memory 42 in response to the operation substance discriminated by the input detection portion 41c and supplies the command code to the transmission/reception controlling portion 41b.

The transmission/reception controlling portion 41b carries out control for transmitting the command code read out by the command reading out portion 41a to the transmission/reception section 43. The transmission/reception section 43 modulates the command code and transmits the modulated command code to a controlling target apparatus on the network 4 by a predetermined communication method.

Further, the transmission/reception controlling portion 41b carries out a reception process of information transmitted thereto from the other apparatus on the network 4, for example, sound volume setting information at present of the apparatus by the transmission/reception section 43. The sound volume setting information of the apparatus is reflected on the substance of the display image on sound volume operation display hereinafter described.

The display controlling portion 41d supplies display data representative of the display substance by the display section 45 to the display driving section 44. For example, the display controlling portion 41d produces display data for causing the display section 45 to execute operation icon display, operation menu display, sound volume operation display and so forth.

Further, the display controlling portion 41d carries out also control for changing the display substance on the display screen in response to a touching operation detected by the input detection portion 41c.

The remote controller 3 reads out, in response to a touching operation by the user, a command code corresponding to the touching operation from the command memory 42 and transmits the command code as a control command to a required apparatus on the network 4.

As described above, the remote controller 3 corresponds to a controlling terminal apparatus.

In the case of the configuration of FIG. 5, the transmission/reception section 43 corresponds to a transmission section and a reception section.

Further, the display section 45 and the display driving section 44 correspond to a display section.

Further, the touch panel sensor 46, position detection section 47 and input detection portion 41c correspond to an operation detection section.

Further, the control section 41 corresponds to a control section.

### <4. Operation Using Sound Volume Operation Display (Sound Volume Balance Maintaining State)>

In the present embodiment, sound volume control for a plurality of sound outputting apparatus, namely, the reproduction apparatus 1 and the network speakers 2B, 2C and 2D on the network 4, can be carried out by the remote controller 3.

Here, sound volume control in the case wherein the sound volumes of the network speakers 2B, 2C and 2D are controlled individually and sound volume control in the case wherein the sound volumes of the reproduction apparatus 1 and the network speakers 2B, 2C and 2D are controlled collectively without losing the sound volume balance among the apparatus are described.

It is to be noted that the state in which the sound volumes of the reproduction apparatus 1 and the network speakers 2B, 2C and 2D are controlled collectively without losing the sound volume balance among the apparatus is hereinafter referred to as “sound volume balance maintaining state” and is distinguished from a “sound volume balance non-maintaining state” hereinafter described.

The display section 45 of the remote controller 3 carries out such GUI display as shown, for example, as a sound volume operation display image 70 in FIG. 6.

The sound volume operation display image 70 includes display images of a master sound volume setting region FDM and individual sound volume setting regions FD1 to FD4.

The individual sound volume setting regions FD1 to FD4 correspond to sound outputting apparatus which become a controlling target. In particular, in the present example, the individual sound volume setting region FD1 is displayed corresponding to the reproduction apparatus 1.

Further, the individual sound volume setting region FD2 is displayed corresponding to the network speaker 2B; the individual sound volume setting region FD3 is displayed corresponding to the network speaker 2C; and the individual sound volume setting region FD4 is displayed corresponding to the network speaker 2D.

On the other hand, while the single master sound volume setting region FDM is displayed, this is used to display an image for collective control of the sound volumes of the sound outputting apparatus.

The master sound volume setting region FDM includes a slide bar SLM such that a set position on the slide bar SLM is indicated by a master knob NM. The master knob NM is moved leftwardly or rightwardly on the slide bar SLM by a touching operation of the user. In other words, the master knob NM is a sliding operation element on the master sound volume setting region FDM.

The master sound volume setting region FDM further includes a numerical value displaying region LM. In the numerical value displaying region LM, a numerical value corresponding to the slide position of the master knob NM, in other words, a numeral value or set value corresponding to a setting change amount of the sound volume by the master sound volume setting region FDM, is displayed. For example, if the master knob NM is positioned centrally on the slide bar SLM as seen in FIG. 6, then “±0” is displayed on the numerical value displaying region LM.

An operation of moving the master knob NM to the left side is an operation of lowering the set sound volume of the plural sound outputting apparatus. When the master knob NM is slid to the left side in this manner, “−1,” . . . , “−50” is displayed on the numerical value displaying region LM. On the other hand, if the master knob NM is slid to the right side to raise the set sound volume, then “+1,” . . . , “+50” is displayed on the numerical value displaying region LM.

It is to be noted that this is an example in the case where the sound volume can be set among 101 stages over the overall length of the slide bar SLM.

The master sound volume setting region FDM further includes a mute button MTM. If the user operates the mute button MTM, then stopping of sound outputting, namely, muting, in the state in which the set sound volumes of the plural sound outputting apparatus remain not changed, can be designated.

Also the individual sound volume setting regions FD1 to FD4 include slide bars SL1 to SL4, knobs N1 to N4, numerical value displaying regions L1 to L4 and mute buttons MT1 to MT4, respectively.

Description is given, for example, of the individual sound volume setting section FD1. By moving the knob N1 leftwardly or rightwardly on the slide bar SL1, the user can increase or decrease the setting of the output sound volume of the reproduction apparatus 1 which is a corresponding sound outputting apparatus. The operation of moving the knob N1 leftwardly is an operation of lowering the set sound value for the reproduction apparatus 1 while the operation of moving the knob N1 rightwardly is an operation of raising the set sound volume for the reproduction apparatus 1.

A portion of the slide bar SL1 positioned on the left side with respect to the knob N1 is drawn in a different color such that the sound volume setting at present looks like a bar graph so that it can be visually recognized readily.

The overall length of the slide bar SL1 corresponds to the sound volume setting of 101 stages, for example, from “0” to “100,” and the sound volume set value at present is displayed on the numerical value displaying region L1. In the case of FIG. 6, the knob N1 is positioned centrally of the slide bar SL1, and consequently, “50” is displayed on the numerical value displaying region L1.

Meanwhile, the mute button MT1 is a display image for carrying out a muting operation of the corresponding sound outputting apparatus. In particular, by operating the mute button MT1, the user can designate stopping of sound outputting, namely, muting, in a state in which the set sound volume remains not changed to the reproduction apparatus 1.

In this manner, by using the individual sound volume setting region FD1, the user can carry out a changing operation of the output sound volume setting for the reproduction apparatus 1 and can confirm the sound volume setting state at present at a glance from the numerical value and the slide bar, namely, the knob position. Also it is possible to temporarily place the reproduction apparatus 1 into a mute state by a muting operation.

Further, with regard to the individual sound volume setting regions FD2 to FD4, the user can carry out a sound volume setting operation and a muting operation arbitrarily and can confirm the sound volume setting state at present individually with regard to the network speakers 2B, 2C and 2D.

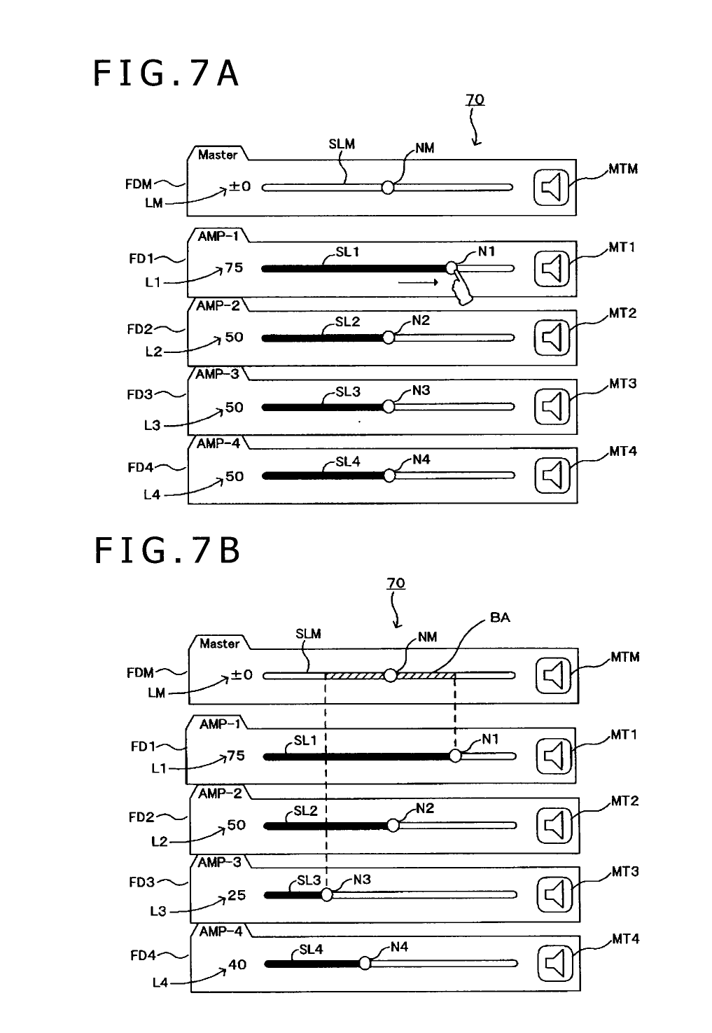

Operations of the individual sound outputting apparatus are illustrated in FIG. 7A.

For example, if the user wants to raise the sound volume setting of the reproduction apparatus 1, then the user would touch the knob N1 and move the knob N1 rightwardly on the slide bar SL1 as seen in FIG. 7A.

The control section 41 shown in FIG. 5 detects such a user operation as just described and controls such that the knob N1 moves following the finger of the user on the display image and also changes the numerical value on the numerical value displaying region L1. Further, in response to the operation, the control section 41 internally updates the output sound value setting with regard to the reproduction apparatus 1 and transmits a control command for raising the sound volume by an amount corresponding to the operation amount, namely, a control command indicative of the updated sound volume setting value, to the reproduction apparatus 1.

For example, if the user moves the knob N1 to the position of “75” as seen in FIG. 7A, then the control section 41 transmits a control command for raising the sound volume setting state to a level corresponding to “75” to the reproduction apparatus 1. The control section 11 of the reproduction apparatus 1 controls the output sound volume setting in the amplification section 17 in response to reception of the control command. Consequently, the output sound volume of the reproduction apparatus 1 in the room A is increased to a level corresponding to “75.”

The user can individually adjust the output sound volume settings of the reproduction apparatus 1 and the network speakers 2B, 2C and 2D by using the individual sound volume setting regions FD1 to FD4 in this manner. For example, if the user wants to lower the sound volume setting for the network speaker 2C of the room C, then the user would slide the knob N3 of the individual sound volume setting region FD3 leftwardly. In response to the sliding movement, a control command for lowering the sound volume setting is transmitted from the remote controller 3 to the network speaker 2C, and the control section 21 of the network speaker 2C carries out control of lowering the sound volume setting in the amplification section 26 in accordance with the control command.

In particular, the user can adjust the sound volume of music or the like played in the rooms A, B, C and D in response to the environment, disposition situation, apparatus performance, purpose of room use and so forth of the rooms A, B, C and D.

For example, FIG. 7B illustrates a state in which sound volume setting for the rooms A, B, C and D is carried out by the user using the individual sound volume setting regions FD1 to FD4.

In this instance, the sound volume of the reproduction apparatus 1 in the room A is adjusted to the level “75”; the sound volume of the network speaker 2B in the room B is adjusted to the level “50”; the sound volume of the network speaker 2C in the room C is adjusted to the level “25”; and the sound volume of the network speaker 2D in the room D is adjusted to the level “40.”

It is to be noted that the control section 41 stores the sound volume set values of the sound outputting apparatus, namely, of the individual sound volume setting regions FD1 to FD4, into an internal memory such as, for example, an internal nonvolatile memory and updates the sound volume set values in response to an operation. Then, the sound volume set values stored in the internal memory are displayed at the numerical value displaying regions L1 to L4.

The display state of the positions of the knobs N1 to N4 and the values of the numerical value displaying regions L1 to L4 in the individual sound volume setting regions FD1 to FD4 changes when the control section 41 updates the sound volume set values stored therein with regard to the sound outputting apparatus.

Actually not only control by the remote controller 3 but also a sound volume operation on the sound outputting apparatus in each room are carried out. For example, an operation of a sound volume operation element on the sound outputting apparatus main body or an operation by a remote controller corresponding to the sound outputting apparatus may be carried out.

The remote controller 3 communicates with the sound outputting apparatus using the transmission/reception section 43 thereof and detects also that a sound volume operation is carried out on each sound outputting apparatus side. If it is detected that a sound volume operation is carried out on any of the sound outputting apparatus, then the control section 41 updates also the sound volume set value with regard to the individual sound volume setting region of the relevant sound outputting apparatus. Also with regard to the display, the control section 41 changes the display of the knob position on the slide bar of the individual sound volume setting region and the display of the numerical value displaying region in response to the actual sound volume setting state of the sound outputting apparatus.

For example, while it is described that, in FIG. 7A, the user moves the knob N1 of the individual sound volume setting region FD1 to the position of “75,” even if the user actually uses the sound volume operation element on the main body of the reproduction apparatus 1 to change the sound volume setting to “75,” the display state on the remote controller 3 is such as illustrated in FIG. 7A.

Consequently, the sound volume operation display image 70 on the remote controller 3 always exhibits a display state representative of actual sound volume setting.

Now, an operation of the master sound volume setting region FDM is described.

It is to be noted that, in the present example, when one of the sound value set values, namely, of the knob positions, of the individual sound volume setting regions FD1 to FD4 does not reach an end point, collective sound volume control is carried out in a sound volume balance maintaining state through the master sound volume setting region FDM.

It is to be noted that the “end point” signifies a state in which the knob (N1 to N4) of an individual sound volume setting region (FD1 to FD4) reaches an end point of the slide bar (SL1 to SL4) and particularly signifies a state in which the sound value set value is “0” or “100.”

While description is hereinafter given, if it is detected that, after an “end point” is reached on a certain one of the individual sound volume setting regions, an operation for the master sound volume setting region FDM is carried out in the operation direction by which the end point is reached on the one individual sound volume setting region on which the end point is reached, then transition from the sound volume balance maintaining state to a sound volume balance non-maintaining state is carried out.

At a point of time at which an end point is not reached on any of the individual sound volume setting regions FD1 to FD4, an operation by the master sound volume setting region FDM is a collective sound volume operation in the sound volume balance maintaining state.

If the user uses the master sound volume setting region FDM, then the individual sound volume setting regions FD1 to FD4 can collectively increase or decrease the sound volume settings of the sound outputting apparatus in the corresponding rooms. Then, an operation in the sound volume balance maintaining state is a collective operation, for example, while a relative sound volume balance set with regard to the sound volume outputting apparatus is maintained as seen in FIG. 7A.

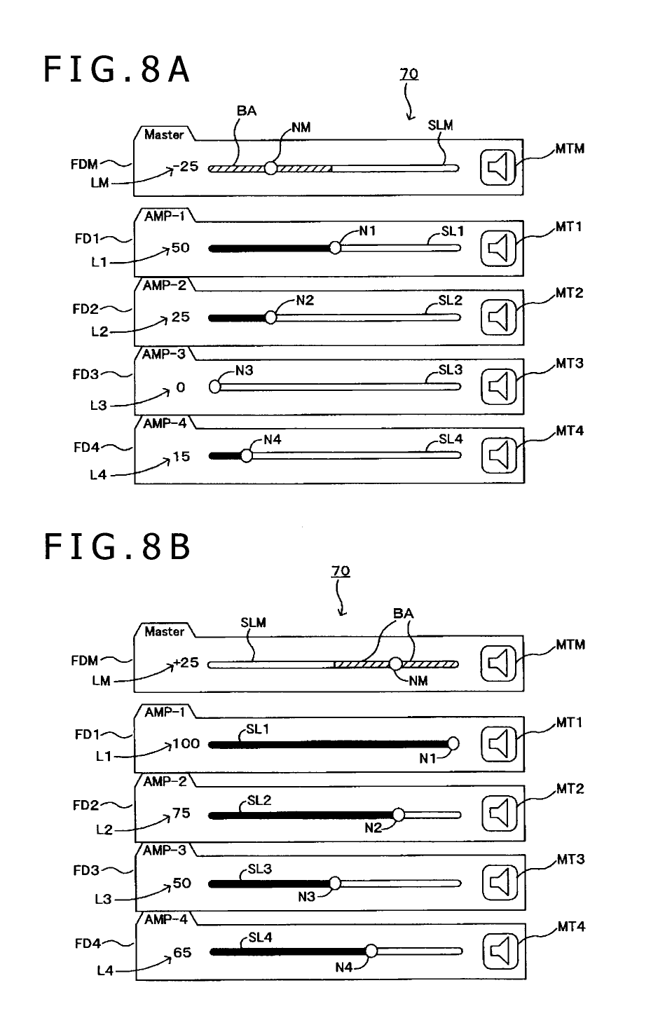

For example, FIG. 8A illustrates a state when the user slides the master knob NM leftwardly to the position of “−25” from the state of FIG. 7B.

The control section 41 of the remote controller 3 detects the user operation of the master knob NM and controls such that the display image of the master knob NM moves together with the finger and also the numerical value on the numerical value displaying region LM changes. Further, with regard to the individual sound volume setting regions FD1 to FD4, the control section 41 controls such that the position of the knobs N1 to N4 moves by “−25” simultaneously with the operation of the master knob NM of the user or immediately after completion of the operation of the master knob NM and also the numerical values on the numerical value displaying regions L1 to L4 are changed to values subtracted by 25 from the formerly displayed values. The control section 41 internally updates the sound volume set values of the sound volume outputting apparatus stored therein to values subtracted by 25.

Then, together with such display control, the control section 41 transmits a control command to decrease the output sound volume settings by the operation amount, that is, by “25” to the reproduction apparatus 1 and the network speakers 2B, 2C and 2D.

In response to reception of the control command, the reproduction apparatus 1 and the network speakers 2B, 2C and 2D individually vary the output sound volume setting thereof. Consequently, the output sound volumes in the rooms A, B, C and D are decreased by a level corresponding to “−25.”

FIG. 8B illustrates a state when the user slides the master knob NM rightwardly to the position of “+25” from the state of FIG. 7B.

The control section 41 of the remote controller 3 detects the user operation of the master knob NM and controls such that the display image of the master knob NM moves together with the finger and also the numerical value on the numerical value displaying region LM changes. In other words, the sound volume set values are updated. Further, with regard to the individual sound volume setting regions FD1 to FD4, the control section 41 controls such that the position of the knobs N1 to N4 moves by “+25” simultaneously with the operation of the master knob NM of the user or immediately after completion of the operation of the master knob NM and also the numerical values on the numerical value displaying regions L1 to L4 are changed to values obtained by adding 25 to the formerly displayed values.

Then, together with such display control, the control section 41 transmits a control command to increase the output sound volume settings by the operation amount, that is, by “25” to the reproduction apparatus 1 and the network speakers 2B, 2C and 2D.

In response to reception of the control command, the reproduction apparatus 1 and the network speakers 2B, 2C and 2D individually vary the output sound volume setting thereof. Consequently, the output sound volumes in the rooms A, B, C and D are increased by a level corresponding to “+25.”

In the cases of FIGS. 8A and 8B, a relative sound volume balance among the sound outputting apparatus of the reproduction apparatus 1 and the network speakers 2B, 2C and 2D is maintained.

In other words, the relative output sound volume differences among the sound outputting apparatus are maintained.

In the present example, in the sound volume balance maintaining state, the control section 41 controls the display section 45 to execute display of indicating an operation range of the master sound volume setting region FDM within which the sound volume balance among the sound outputting apparatus can be maintained.

For example, in FIGS. 7B, 8A and 8B, an example is shown in which the operation range of the master sound volume setting region FDM within which the sound volume balance can be maintained is displayed as a balance operation range bar BA.

The balance operation range bar BA is displayed in such a manner that a bar projects leftwardly and rightwardly from the master knob NM in the slide bar SLM such that it demonstrates to the user that the sound volume balance is maintained if the balance operation range bar BA is within a range within which it contacts with an end portion of the slide bar SLM.

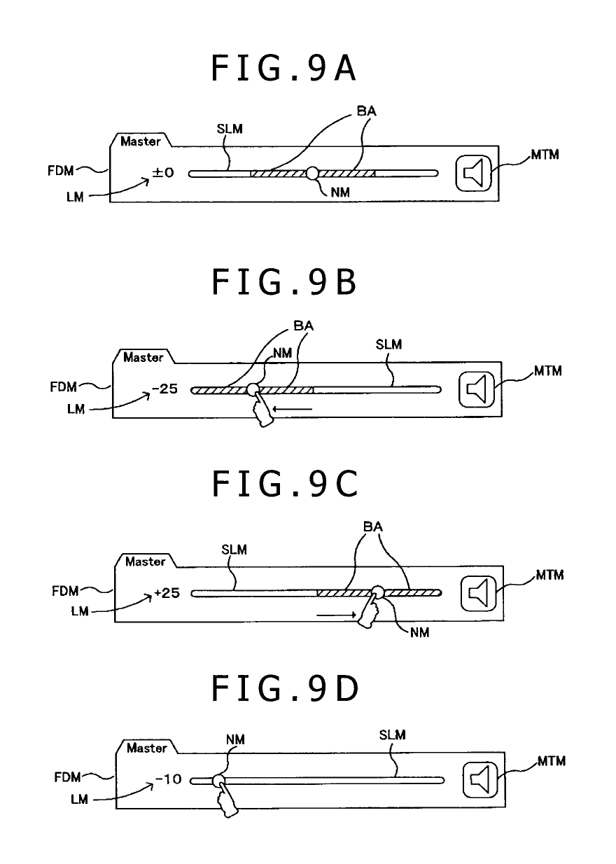

This is described with reference to FIGS. 9A to 9D. FIG. 9A illustrates a state in which the master knob NM is at the position of “±0.” FIG. 9B illustrates a state in which the master knob NM is slid leftwardly from the state of FIG. 9A. In FIG. 9B, the sliding operation is carried out until the balance operation range bar BA reaches the left end of the slide bar SLM.

Meanwhile, FIG. 9C illustrates another state in which the master knob NM is slid rightwardly from the state of FIG. 9A. In FIG. 9C, the sliding operation is carried out until the balance operation range bar BA reaches the right end of the slide bar SLM.

The balance operation range bar BA demonstrates to the user that the sound volume balance is maintained within the range from the state of FIG. 9B to the state of FIG. 9C.

While description is hereinafter given, if the master knob NM is operated in the leftward direction further from the state of FIG. 9B, then the control section 41 of the remote controller 3 enters a sound volume balance non-maintaining state. Thereupon, though not shown, the balance operation range bar BA is not displayed as seen in FIG. 9D.

Similarly, if the master knob NM is operated in the rightward direction further from the state of FIG. 9C, then the control section 41 enters a sound volume balance non-maintaining state. Thereupon, though not shown, the balance operation range bar BA is not displayed.

Accordingly, the user can recognize that a master operation by which the sound volume balance is maintained is being carried out as far as the balance operation range bar BA is displayed. In addition, the user can discriminate from the balance operation range bar BA to which position the operation of the master knob NM can be carried out in order to maintain the sound volume balance.

It is to be noted that, in order to indicate the range within which the sound volume balance can be maintained, the length, namely, the display range, of the balance operation range bar BA is determined in response to the sound volume set values by the individual sound volume setting regions FD1 to FD4 as shown in FIG. 7B. In particular, the right end of the balance operation range bar BA is adjusted to the highest sound volume set value, in the example illustrated in FIG. 7B, to the set value of the individual sound volume setting region FD1 while the left end of the balance operation range bar BA is adjusted to the lowest sound volume set value, in the example illustrated in FIG. 7B, to the set value of the individual sound volume setting region FD3.

In the state illustrated in FIG. 9B, the left end of the balance operation range bar BA contacts with the left end of the slide bar SLM. This is a state in which the collective sound value setting is moved to “−25,” for example, by the master knob NM.

In particular, if the state of FIG. 9B is viewed from the entirety of the sound volume operation display image 70, then this is the state of FIG. 8A. At this time, on the individual sound volume setting region FD3, namely, on the network speaker 2C, which indicates the lowest sound volume setting, the sound value setting is lowered to the level “0.”

Consequently, even if the master knob NM is slid leftwardly further and a control command corresponding to the sliding movement is transmitted to the sound outputting apparatus, since the actual output sound volume of the network speaker 2C is 0 already, it does not decrease any more. After all, the set sound volumes of the reproduction apparatus 1 and the network speakers 2B and 2D are lowered. In this instance, the sound volume balance among the sound outputting apparatus is lost.

Further, in the state of FIG. 9C described above, the right end of the balance operation range bar BA reaches the right end of the slide bar SLM. This is a state in which the collective sound volume is set to “+25,” for example, by the master knob NM.

In particular, if the state of FIG. 9B is viewed from the entirety of the sound volume operation display image 70, then this is the state of FIG. 8B. At this time, on the individual sound volume setting region FD1, namely, on the reproduction apparatus 1, which indicates the highest sound volume setting, the sound value setting is raised to the level “100,” namely, to the maximum level.

Consequently, even if the master knob NM is slid rightwardly further and a control command corresponding to the sliding movement is transmitted to the sound outputting apparatus, increase of the sound volume set value on the reproduction apparatus 1 is not carried out any more. Meanwhile, the set sound volumes of the network speakers 2B, 2C and 2D are raised. In this instance, the sound volume balance among the sound outputting apparatus is lost.

In short, if a sliding operation is carried out within the range demonstrated by the balance operation range bar BA, then collective control can be carried out with the sound volume balance maintained.

The user can recognize the sliding range of the master knob NM from the display of the balance operation range bar BA and easily execute an operation for collective control with the sound volume balance maintained.

It is to be noted that, in the foregoing description, an example of the balance operation range bar BA which interlocks with the master knob NM is described as the display image which clearly indicates an operation range within which the sound volume balance can be maintained. However, also other display examples of the balance operation range bar BA having different modes are available.

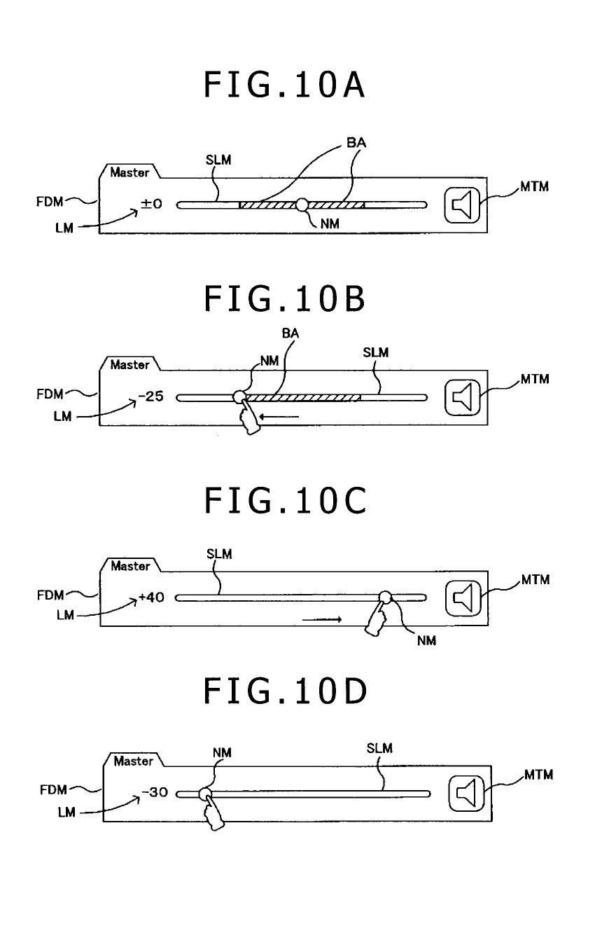

FIGS. 10A to 10D illustrate an example wherein the display of the balance operation range bar BA is not interlocked with the master knob NM.

FIG. 10A shows the master sound volume setting region FDM in the state of FIG. 7B.

In the case of the present example, the balance operation range bar BA is displayed in response to the position of the knob on the individual sound volume setting regions FD1 to FD4 at this point of time, which is similar to that in FIG. 7B. However, even if the user operates the master knob NM, the balance operation range bar BA does not move.

For example, even if the user moves the master knob NM leftwardly as seen in FIG. 10B, the display position of the balance operation range bar BA remains same as that in FIG. 10A.

If the user operates the master knob NM leftwardly further, then a sound volume balance non-maintaining state hereinafter described is entered. In this instance, the balance operation range bar BA is erased as seen in FIG. 10D. Similarly, if the user operates the master knob NM rightwardly exceeding the balance operation range bar BA of FIG. 10A, then also in this instance, a sound volume balance non-maintaining state is entered, and the balance operation range bar BA is erased as seen in FIG. 10C.

In short, in the present example, the user can discriminate a sound volume balance non-maintaining state and a sound volume balance maintaining state from each other from presence or absence of the display image of the balance operation range bar BA. Thus, the user can recognize that a master operation with the sound volume balance maintained is being carried out as far as the balance operation range bar BA remains displayed. In addition, the user can recognize that, in order to maintain the sound volume balance, only it is necessary to operate the master knob NM within the range of the balance operation range bar BA.

For example, as in the examples described above, the control section 41 controls the display section 45 to execute display of different display modes between a sound volume balance maintaining state and a sound volume balance non-maintaining state as presence/absence of the display image of the balance operation range bar BA.

Further, in the sound volume balance maintaining state, the control section 41 controls the display section 45 to display an image indicative of the operation range of the master sound volume setting region FDM within which the sound volume balance among the sound outputting apparatus can be maintained through the balance operation range bar BA.

It is to be noted that the display image for indicating the operation range of the master sound volume setting region FDM within which the sound volume balance among the sound outputting apparatus can be maintained in the sound volume balance maintaining state may be implemented in further various examples.

Such an example may be possible wherein the balance operation range bar BA indicates such displays as illustrated in FIGS. 9A to 9D or 10A to 10D in such a form that part of the slide bar SLM is changed in color or wherein, for example, the length of the slide bar SLM itself is displayed only within a range within which the sound volume balance can be maintained.

Further, while, in the examples of FIGS. 9A to 9D and 10A to 10D, the balance operation range bar BA is displayed within the slide bar SLM, the balance operation range bar BA may otherwise be displayed separately from and in a juxtaposed relationship with the slide bar SLM.

In any case, only it is necessary for the display form to allow the user to discriminate the operation range of the master knob NM within which the sound volume balance can be maintained.

In the following, description is given further of examples in which such a balance operation range bar BA as described hereinabove with reference to FIGS. 9A to 9D is used.

As described hereinabove with reference to FIG. 7B, the range within which the sound volume balance can be maintained depends upon the sound volume setting of the individual sound volume setting regions FD1 to FD4, namely, of the sound outputting apparatus. Therefore, in response to a variation operation of the sound volume setting on any of the individual sound volume setting regions FD1 to FD4, also the display of the length of the balance operation range bar BA and the position of the master knob NM on the master sound volume setting region FDM is changed.

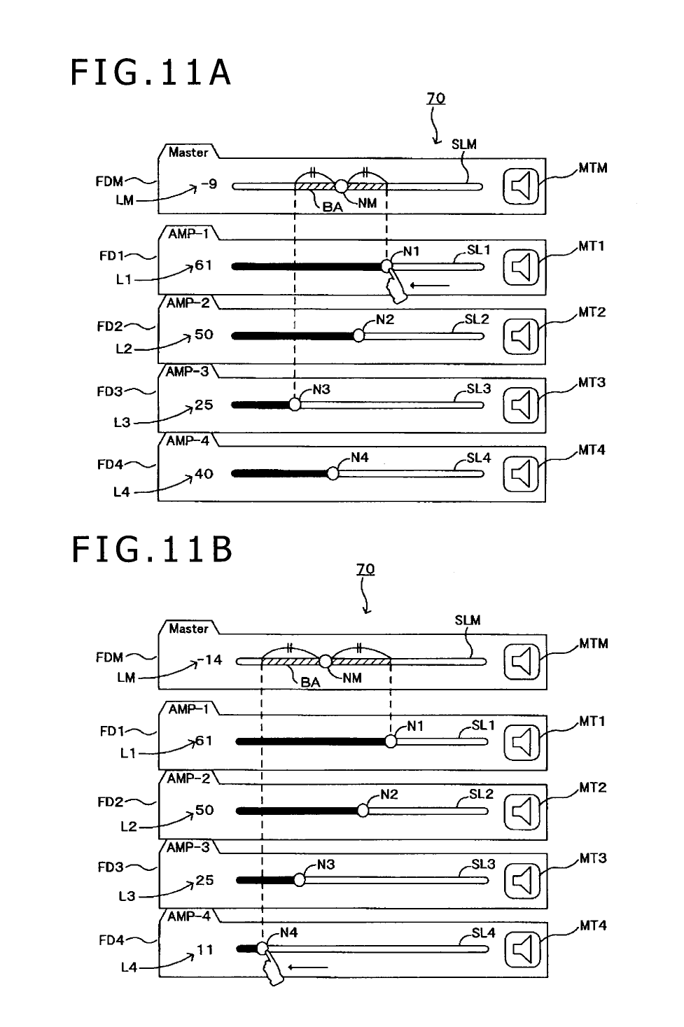

For example, it is assumed that the user operates the knob N1 of the individual sound volume setting region FD1 as seen in FIG. 11A from the state of FIG. 7B. More particularly, it is assumed that the sound volume setting of the reproduction apparatus 1 by the individual sound volume setting region FD1 is lowered from the level “75” to another level “61.”

In the state of FIG. 11A, the maximum sound volume set value is the set value of the individual sound volume setting region FD1 similarly as in the case of FIG. 7B. However, the sound volume set value itself is lowered to the level “61.” In response to this, the right end of the balance operation range bar BA is changed to a position in accordance with the position of the knob N1 on the individual sound volume setting region FD1. The left end of the balance operation range bar BA remains at the position of the knob N3 of the individual sound volume setting region FD3.

Simultaneously, the position of the master knob NM is disposed at the center of the range indicated by the balance operation range bar BA. Therefore, in this instance, the master knob NM is displayed at a position corresponding to “−9.” In other words, the master knob NM is positioned such that the leftwardly and rightwardly extending portions of the balance operation range bar BA are equal to each other.

It is to be noted that, while, in FIG. 11A, the numerical value displaying region LM indicate “−9” in response to the change of the position of the master knob NM, since, in this instance, the master knob NM is not actually operated, even if the position of the master knob NM corresponds to “−9,” the numerical value displaying region LM may remain displaying “±0.” In other words, the numerical value on the numerical value displaying region LM may be any of a value corresponding to the position of the master knob NM on the display and a value corresponding to the actual operation amount of the master knob NM.

FIG. 11B illustrates a state in which the user lowers the knob N4 of the individual sound volume setting region FD4 to the level “11” from the state of FIG. 11A.

In this instance, the highest sound volume set value is “61” of the individual sound volume setting region FD1 and the lowest sound volume set value is “11” of the individual sound volume setting region FD4, and the balance operation range bar BA is displayed within a range defined by the highest and lowest sound volume set values. Further, the master knob NM is displayed at the center of the range. As a result, the master knob NM is displayed at the position corresponding to “−14.” Also in this instance, the numerical value displaying region LM may remain displaying “±0.”

The operable range of the master knob NM with the sound volume balance maintained varies depending upon the change of the sound volume setting of each sound outputting apparatus. Therefore, also the display range of the balance operation range bar BA and the display position of the master knob NM are changed in response to an operation of the individual sound volume setting regions FD1 to FD4 as described hereinabove. Since the display range and the display position just mentioned are changed in this manner, the user can always recognize the sliding range, within which the balance is maintained by an operation using the master knob NM, visually clearly.

It is to be noted that the description given just above relates to the example of FIGS. 9A to 9D in which the balance operation range bar BA is interlocked with the position of the master knob NM. However, also in an example wherein the balance operation range bar BA is displayed fixed as in the case of FIGS. 10A to 10D, the display range of the balance operation range bar BA and the position of the master knob NM are changed in response to an operation of the individual sound volume setting regions FD1 to FD4. This is because the range within which the sound volume balance can be maintained irrespective of an operation of the master knob NM is changed by the sound volume setting state of each sound outputting apparatus.

Operation and display forms in the sound volume balance maintaining state through an operation of the master knob NM have been described above.

In particular, in the sound volume balance maintaining state, when an operation of the master sound volume setting region FDM is detected, the control section 41 of the remote controller 3 uses a value corresponding to a detected operation amount of the master knob NM to change the sound volume setting of the individual sound volume setting regions. Further, the control section 41 generates a control signal indicative of the new sound volume setting and controls the transmission/reception section 43 to transmit and output the control signal.

More particularly, the control section 41 adds or subtracts a value corresponding to an operation amount itself of the master knob NM to or from the sound volume set values of the individual sound volume setting regions FD1 to FD4 to change the sound volume settings of the sound outputting apparatus.

Here, if the slide bar lengths, namely, the variable step numbers, of the master sound volume setting region FDM and the individual sound volume setting regions FD1 to FD4 are equal to each other, for example, 101 steps as in the example of the figures described hereinabove, then the value corresponding to the detected operation amount itself of the master knob NM is the value of the operation amount itself, namely, of the step number. In this instance, the value of the operation amount of the master knob NM, namely, the step number, may be added or subtracted on the individual sound volume setting regions FD1 to FD4.

For example, if an operation to increase the sound volume by 15 steps from “±0” to “+15” is carried out by the master knob NM, then the sound volume set values may be increased by 15 steps on the individual sound volume setting regions FD1 to FD4.

On the other hand, if an operation to decrease the sound volume by 10 steps from “±0” to “−10” is carried out by the master knob NM, then the sound volume set values may be subtracted by 10 steps on the individual sound volume setting regions FD1 to FD4.

On the other hand, the value corresponding to the detected operation amount itself of the master knob NM here is, if the slide bar lengths, namely, the variable step numbers, of the master sound volume setting region FDM and the individual sound volume setting regions FD1 to FD4 are different from each other, given as a value representative of a ratio of the operation amount of the master knob NM to the variable step number.

For example, it is assumed that the variable step number corresponding to the overall length of the slide bar SLM of the master sound volume setting region FDM is “100” and the variable step number corresponding to the overall length of the slide bars SL1 to SL4 of the individual sound volume setting regions FD1 to FD4 is “150” equal to 1.5 times the overall length of the slide bar SLM.

In this instance, for example, if an operation for increasing the sound volume by 10 steps from “±0” to “+10” is carried out by the master knob NM, then the sound volume set value on the individual sound volume setting regions FD1 to FD4 may be increased by 15 steps by increasing the step number to 1.5 times, namely, to 10×1.5=15.

On the other hand, for example, if an operation for decreasing the sound volume by 20 steps from “±0” to “−20” by the master knob NM, then the sound value set value on the individual sound volume setting regions FD1 to FD4 may be decreased by 30 steps by increasing the step number to 1.5 times, namely, to −20×1.5=−30.

In any case, in the sound volume balance maintaining state, where k is given as

k=(variation step number of individual sound volume setting regions FD1 to FD4)/(variation step number of master sound volume setting region FDM)

the addition/subtraction amount to/from the sound volume set value of the individual sound volume setting regions is given by

addition/subtraction amount=master nob operation amount×k

### <5. Nob Lock Operation>

Now, a knob lock operation is described.

Although the user can carry out collective sound volume setting or individual sound volume setting by touching and slide operating any of the master knob NM and the knobs N1 to N4, the user may possibly touch with a finger or the like the display section 45 in the form of a touch panel screen inadvertently to carry out unintended or unexpected sound volume variation setting. This is inconvenient after the user carries out a sound volume setting operation with an appropriate balance taken into consideration.

Therefore, such locking process as does not allow sliding movement of the master knob NM or the knobs N1 to N4, namely, such a process as to inhibit operation of the master knob NM and the knobs N1 to N4, even if they are touched inadvertently, can be carried out.

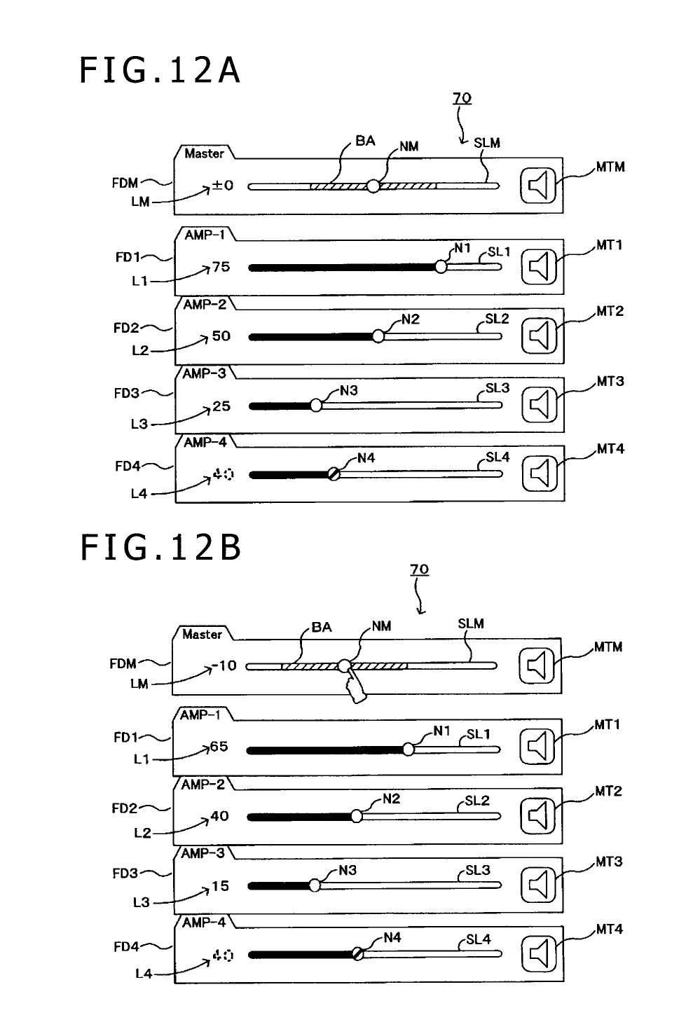

For example, FIG. 12A illustrates a state in which the knob N4 is locked after sound volume setting of the sound outputting apparatus is carried out as seen in FIG. 7B.

It is assumed that, if the user taps or slightly touches an arbitrary knob with a finger thereof, then the knob is locked. If the user taps the knob N4, then the control section 41 places the knob N4 into a locked state. On the display, the display image of the knob N4 is changed over to a knob display image in a locked state as seen in FIG. 12A. Or, the numerical value on the numerical value displaying region L4 may be displayed faintly such as, for example, in inactive display as seen in FIG. 12A. Or the individual sound volume setting region FD4 may be entirely displayed in inactive display.

After the knob N4 is placed into a locked state, if the control section 41 detects a sliding movement of the knob N4, then the control section 41 invalidates the operation and does not carry out a process for sound volume setting change or display change.

Also the other knobs N1 to N3 and the master knob NM may be locked in a similar manner. For example, if the user taps the master knob NM, then the control section 41 places the master knob NM into a locked state and changes over the display image of the master knob NM to a display image which demonstrates the locked state of the master knob NM.

In order to cancel the locked state of a knob, namely to unlock a knob, the user may tap the locked knob again. For example, in order to cancel the lock of the knob N4 from the state of FIG. 12A, the user would tap the display image of the knob N4. Consequently, the control section 41 returns the display image to that of FIG. 7B and accepts a later operation input to the knob N4 as an effective operation input.

Further, for example, if the knobs N1 to N4 of the individual sound volume setting regions FD1 to FD4 are all placed into a locked state, then also the master knob NM may be automatically placed into a locked state similarly. This is because, when all of the knobs N1 to N4 are in a locked state, in other words, when the sound volume settings of all of the sound outputting apparatus are fixed, also a collective operation by the master knob NM cannot be carried out and accordingly it is suitable to demonstrate to the user that an operation of the master knob NM is invalid.

Incidentally, if the master knob NM is operated when some knob or knobs are locked while the other or others are not locked on the individual sound volume setting regions FD1 to FD4, then an operation by the master knob NM may be reflected on any knob which is not in a locked state.

For example, it is assumed that, in a state in which the knob N4 is locked and the knobs N1 to N3 are not locked as seen in FIG. 12A, the master knob NM is operated to “−10” as seen in FIG. 12B.

At this time, the individual sound volume setting region FD4 is not interlocked and the position of the knob N4 remains fixed. Then, the individual sound volume setting regions FD1 to FD3 are interlocked and the knobs N1 to N3 are moved to the positions lowered by “10.” Further, a command to set the sound volume setting to “−10” is transmitted to the reproduction apparatus 1 and the network speakers 2B and 2C.

In this manner, even if some knob is locked, if the knob of some other individual sound volume setting region is not locked, then the individual sound volume setting region is controlled in an interlocked relationship in response to an operation of the master sound volume setting region FDM. This can achieve effective utilization of the master sound volume setting region FDM appropriately.

Further, in this instance, collective control by the master knob NM is carried out except the locked knob, namely, except the sound outputting apparatus whose sound volume setting is locked. This is a sound volume setting variation operation with the sound volume balance maintained except the locked sound outputting apparatus. Therefore, when a certain knob is placed into a locked state, the display of the balance operation range bar BA of the master knob NM and the position of the master knob NM may be changed within a range between the maximum set value and the minimum set value except the knob.

For example, if the knob N1 is locked in the state of FIG. 7B, then if the knob N1 is excepted, then the maximum set value is the level “50” by the knob N2. Therefore, the range between the level “25” of the knob N3 as the minimum value and the level “50” of the maximum set value is indicated by the balance operation range bar BA.

Naturally, also in the case where the locking of the certain knob is canceled, if the range between the maximum set value and the minimum set value changes by including the knob, then also the display of the balance operation range bar BA and the display of the position of the master knob NM are changed.

### <6. Muting Operation>

In the present embodiment, an operation of temporarily placing the sound outputting apparatus into a mute state of the zero sound volume without changing the sound volume set values of the sound outputting apparatus using the remote controller 3 can be carried out.

As described hereinabove, the mute buttons MTM and MT1 to MT4 are provided for the master sound volume setting region FDM and the individual sound volume setting regions FD1 to FD4, respectively. The user can input a mute instruction by tapping an arbitrary mute button.

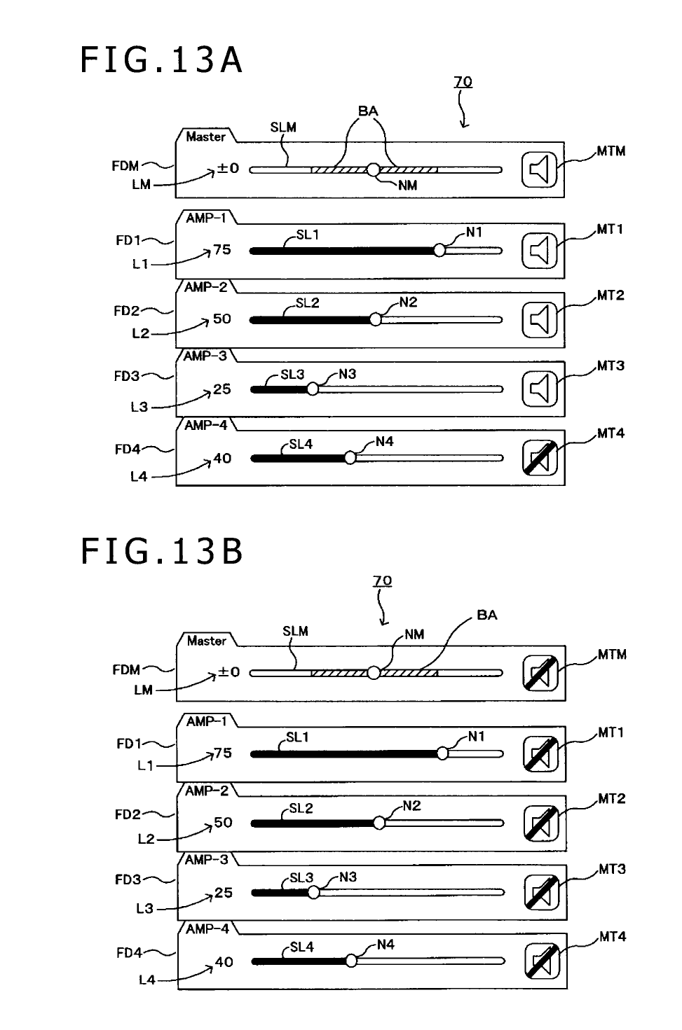

FIG. 13A illustrates a state, for example, when the user taps the mute button MT4 of the individual sound volume setting region FD4 from the state of FIG. 7B.

In response to the tapping of the mute button MT4, the control section 41 carries out a process of transmitting a control command for the muting to the network speaker 2D corresponding to the individual sound volume setting region FD4. The control section 21 of the network speaker 2D controls the amplification section 26 into a mute state, namely, into a sound-deadening state, in response to reception of the control command. In other words, output sound from the speaker section 27 is stopped. It is to be noted that this is not to change the sound volume setting to zero but to stop sound outputting while the sound volume setting is maintained.

Further, the control section 41 of the remote controller 3 changes over the display image of the mute button MT4 of the individual sound volume setting region FD4 to a display image which demonstrates that the network speaker 2D is in a mute state as seen in FIG. 13A.

Also when any of the mute buttons MT1 to MT3 is tapped, the control section 41 transmits a similar control command to a corresponding sound outputting apparatus and carries out changeover of the display of a corresponding one of the mute buttons MT1 to MT3.

A state when the mute button MTM of the master sound volume setting region FDM is tapped is illustrated in FIG. 13B. In the present example, when the mute button MTM of the master sound volume setting region FDM is operated, a muting process of all sound outputting apparatus is carried out.

In particular, the control section 41 carries out a process of transmitting a control command for a muting operation to the reproduction apparatus 1 and the network speakers 2B, 2C and 2D corresponding to the individual sound volume setting regions FD1 to FD4, respectively. Consequently, a muting process of stopping sound outputting while the sound volume settings are maintained is carried out by the sound outputting apparatus.

Further, the control section 41 controls the display of the mute buttons MTM and MT1 to MT4 to a display image, as shown in FIG. 13B, which demonstrates that the reproduction apparatus 1 and the network speakers 2B, 2C and 2D are in a mute state.

It is to be noted that, if the mute buttons MT1 to MT4 of the individual sound volume setting regions FD1 to FD4 are individually tapped and, as a result, all of the sound outputting apparatus, namely, all of the reproduction apparatus 1 and the network speakers 2B, 2C and 2D, are placed into a mute state, then the display image of the mute button MTM of the master sound volume setting region FDM is preferably changed over to a display image of a mute state. In other words, also in this instance, the display image is placed into the state of FIG. 13B.

If the user wants to cancel a mute state, then it may tap the mute button in the mute state.

For example, if the user taps, in the state of FIG. 13A, the mute button MT4 of the individual sound volume setting region FD4, then the mute state of the network speaker 2D is canceled.

In response to the tapping of the mute button MT4 for the cancellation of a mute state, the control section 41 carries out a process of transmitting a control command for the cancellation of a mute state to the network speaker 2D corresponding to the individual sound volume setting region FD4. The control section 21 of the network speaker 2D cancels the mute state of the amplification section 26 in response to reception of the control command. Consequently, sound outputting at a level corresponding to the sound volume setting at the point of time is re-started from the speaker section 27.

Further, the control section 41 of the remote controller 3 changes over the display image of the mute button MT4 of the individual sound volume setting region FD4 to a display image in an ordinary state as seen in FIG. 7B.

Also when any other one of the mute buttons MT1 to MT3 is tapped in a muting state, the control section 41 carries out transmission of a similar control command for the cancellation of the mute state to the corresponding sound outputting apparatus and display changeover of the mute buttons MT1 to MT3.

In the case where all sound outputting apparatus are placed in a mute state and the mute button MTM of the master sound volume setting region FDM is displayed in a mute state as seen in FIG. 13B, the mute state can be cancelled collectively by tapping the mute button MTM.

In particular, if, in the state of FIG. 13B, the mute button MTM of the master sound volume setting region FDM is operated, then the control section 41 carries out a process of transmitting a control command for the instruction to cancel the mute state to the reproduction apparatus 1 and the network speakers 2B, 2C and 2D corresponding to the individual sound volume setting regions FD1 to FD4, respectively. Consequently, each sound outputting apparatus re-starts sound outputting in accordance with the sound volume setting at the point of time.

Further, the control section 41 returns the display of the mute buttons MTM and MT1 to MT4 to the display demonstrating the ordinary state as seen in FIG. 7B.

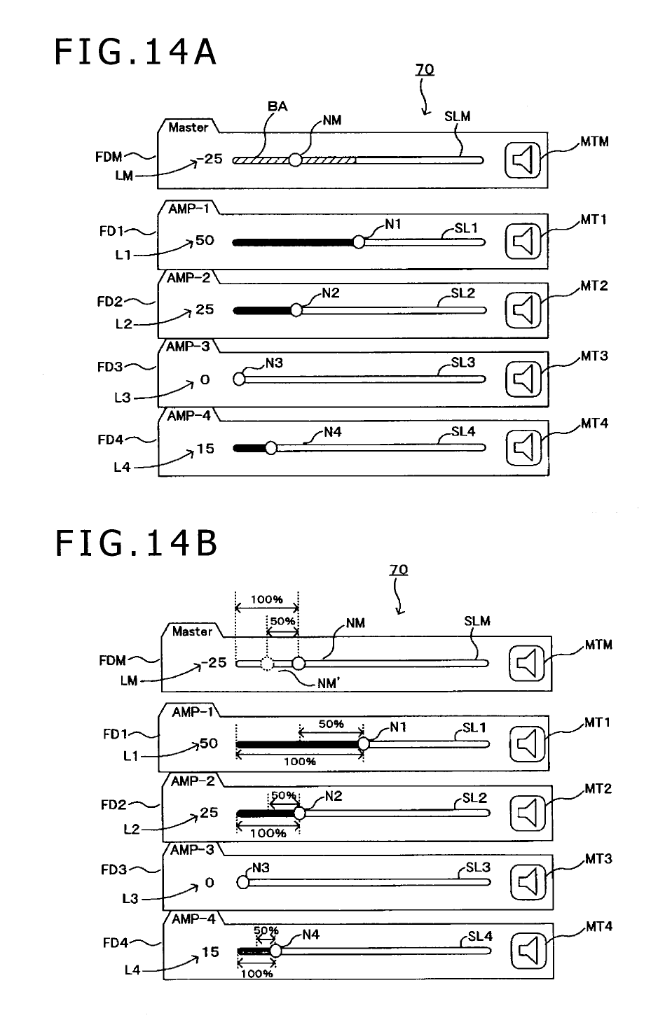

It is to be noted that, even when some or all of the sound outputting apparatus are in a mute state, for example, as seen in FIGS. 14A and 14B, a user operation using the master knob NM or the knobs N1 to N4 may be permitted. In other words, the sound volume setting of some or all of the sound outputting apparatus may be changed in response to a sliding operation of the knobs by the user. In this instance, the changed sound volume setting may be reflected on the output sound after the mute state is cancelled.

### <7. Operation Using Sound Volume Operation Display (Sound Volume Balance Non-Maintaining State)>

Although, in response to an operation in the sound volume balance maintaining state described above, the sound volumes of the individual sound outputting apparatus are collectively controlled while the sound volume balance is maintained, it may be sometimes desired to collectively control the sound volumes of the reproduction apparatus 1 and the network speakers 2B, 2C and 2D even if the sound volume balance among the apparatus is lost.

Therefore, in the present embodiment, it is made possible to further carry out an operation of the master sound volume setting region FDM exceeding the operation in the sound volume balance maintaining state described hereinabove.

In the present embodiment, when the sound volume setting of all of the individual sound volume setting regions FD1 to FD4 is not in a state at the end point of the sound volume setting variation range, the control section 41 carries out control of the sound volume balance maintaining state described hereinabove. In short, the control of the sound volume balance maintaining state is carried out in the case where the master knob NM is operated in a state in which all of the knobs N1 to N4 are not positioned at end portions of the slide bars SL1 to SL4, in other words, in a state in which the sound volume setting values are any other than “0” and “100.”

When the end point of one of the individual sound volume setting regions FD1 to FD4 is reached by an operation of the master sound volume setting region FDM and the operation of the master knob NM of the master sound volume setting region FDM is further continued in the same operation direction, the control section 41 enters the sound volume balance non-maintaining state and carries out processing. It is to be noted that end points of two or three of the four individual sound volume setting regions FD1 to FD4 may be reached at the same time, and also in this instance, the sound volume balance non-maintaining state is entered.

In other words, if it is detected that, after the sound volume setting of one individual sound volume setting region is changed to that at the end point or after the sound volume setting of a plurality of individual sound volume setting regions is changed to that at the end point at the same time, the operation of the master sound volume setting region FDM is carried out in the direction of the operation by which the relevant individual sound volume setting region or regions have been moved to the end point, then the control section 41 enters the sound volume balance non-maintaining state from the sound volume balance maintaining state and carries out processing.

Then, if, in the sound volume balance non-maintaining state, an operation for the master sound volume setting region FDM is detected, then the control section 41 changes the sound volume setting of each of the individual sound volume setting regions using a value, which has a ratio equal to the ratio of the detected operation amount to an operable amount of the master sound volume setting region upon the operation, with respect to an operable amount of each of the individual sound volume setting regions. Then, the control section 41 generates a control signal for the instruction of a new sound volume setting and transmits and outputs the control signal from the transmission/reception section 43 to the sound outputting apparatus.

It is to be noted that, although processes in the sound volume balance non-maintaining state are described in connection with an example after one of the individual sound volume setting regions FD1 to FD4 reaches the end point of the sound volume setting variation range. However, also in the case where a plurality of, namely, two or three, individual sound volume setting regions reach the end point at the same time, similar processes to those carried out when one individual sound volume setting region reaches the end point are carried out.

However, if all of the individual sound volume setting regions FD1 to FD4 reach the end point, then the master sound volume setting region FDM cannot be further operated in a direction same as the direction in which they have been operated to reach the end point or a further operation in the direction is meaningless. Therefore, in this instance, the operation described below is not carried out.

FIG. 14A illustrates a state in which, for example, the master knob NM is slid leftwardly to the position of −25 from the state of FIG. 7B.

This is a state when the master knob NM is operated to a lower operation limit while the sound volume balance among the reproduction apparatus 1 and the network speakers 2B, 2C and 2D is maintained. In this instance, the sound volume setting of the individual sound volume setting region FD3 reaches the level “0” at the end point of the sound volume setting variation range.

As described hereinabove, if, in this instance, the user tries to operate the master knob NM leftwardly further, then the sound volume balance cannot be maintained. However, also in such a case, it is sometimes desired to collectively operate the remaining three apparatus, and therefore, a process in the sound volume balance non-maintaining state is carried out.

In this instance, the ratio of the detected operation amount to the operable amount of the master sound volume setting region FDM is multiplied to the sound volume set values of the individual sound volume setting regions FD1 to FD4 to change the sound volume setting of the sound outputting apparatus as seen in FIG. 14B. Then, control signals for the instruction of new sound volume settings are generated and then transmitted and outputted from the transmission/reception section 43.

For example, it is assumed that, in FIG. 14B, the master knob NM is operated further in the leftward direction to a position of a master knob NM′ indicated by a broken line.

This is a state in which, where the operable amount of the master knob NM in the leftward direction at a stage prior to the operation is represented by 100%, the master knob NM is operated by 50%, namely, by one half of the operable amount.

The ratio of the detected operation amount to the operable amount of the master sound volume setting region FDM in this instance is 50%.

The control section 41 stores the sound volume set values of the individual sound volume setting regions FD1 to FD4 as control change point information before it enters the sound volume balance non-maintaining state.

For example, in the case of FIG. 14B, the control section 41 stores, as control change point information, the set value “−25” of the master sound volume setting region FDM and the sound volume set values “50,” “25,” “0” and “15” of the individual sound volume setting regions FD1 to FD4.

Then, 50% (=0.5) of the operation ratio of the master knob NM is multiplied to the sound value set values “50,” “25,” “0” and “15” of the individual sound volume setting regions FD1 to FD4 to obtain new sound volume set values of the individual sound volume setting regions.

It is to be noted that the control section 41 successively updates and stores the sound volume set values at different points of time separately from the control change point information. In other words, the control section 41 stores the sound volume set values of the sound outputting apparatus at present irrespective of the sound volume balance maintaining state or the sound volume balance non-maintaining state.

After all, if the master knob NM is operated by 50% of the remaining operable mount, in the leftward direction, then the sound volume set values of the individual sound volume setting regions FD1, FD2 and FD4 are changed to values of 50% from the values at present.

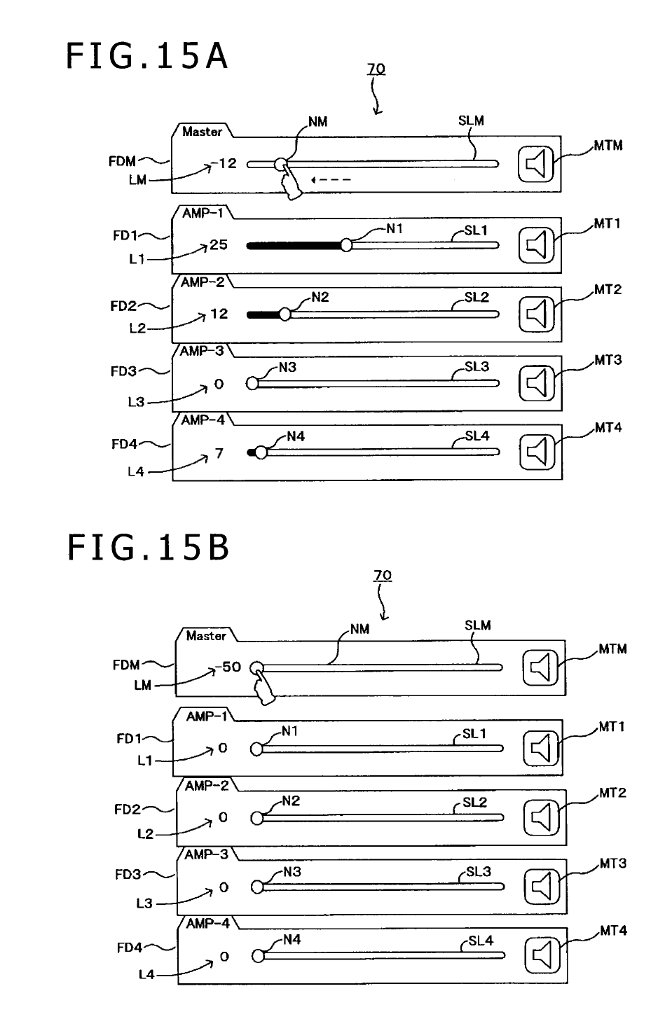

For example, if the master knob NM is operated to decrease 50% from “−25” to “−12” as seen in FIG. 15A (in the example described now, the ratio and the sound value set value are rounded down), then the individual sound volume setting regions FD1, FD2 and FD4 are changed to states of FD1=“25,” FD2=“12” and FD4=“7” in response to the operation. The sound volume set value of the individual sound volume setting region FD3 remains “0.”

In particular, where, in regard to each individual sound volume setting region, the sound volume set value stored as the control change point information upon transition to the sound volume balance non-maintaining state is represented by “VLc” and the ratio of the operation amount to the operable amount of the master knob NM is represented by “R,” a new sound volume set value VLn of the individual sound volume setting region is given by a following formula.

VLn=VLc×R

The ratio R is given, using a set value VMc of the master sound volume setting region FDM stored as the control change point information and a set value VMn of the master sound volume setting region FDM after the operation of the master knob NM, by a following formula.

R=VMn/VMc

It is to be noted that VLc may be a sound volume set value of the individual sound volume setting region immediately before the operation of the master knob NM and also the set value VMn may be a set value of the master sound volume setting region FDM immediately before the operation of the master knob NM.

In the case of such an operation in the leftward direction, in the direction in which the sound volume level decreases toward 0, as just described, the sound volume set value VLc at present is the operable amount of each of the individual sound volume setting regions and the sound volume setting of each of the individual sound volume setting regions is changed using a value (VLc×R), which has a ratio equal to the ratio R of the operation amount of the master knob NM, with respect to the operable amount of each of the individual sound volume setting regions.

After all, by changing the sound volume setting amount of each of the individual sound volume setting regions FD1 to FD4 in response to the ratio of the operation of the master knob NM in the leftward direction, if the master knob NM is finally operated to the left end of the slide bar SLM, then the sound volume set values of all of the individual sound volume setting regions FD1 to FD4 become equal to “0” as seen in FIG. 15B.

In particular, after the sound volume balance is lost, by changing not the operation step number of the master knob NM but the sound volume set values of the individual sound volume setting regions FD1 to FD4 in response to the operation ratio, the sound volume of all of the sound outputting apparatus can be brought to the zero state by an operation of the master knob NM. Accordingly, if the user touches the master knob NM with a finger and moves the master knob NM to the left end portion, then it is possible to cause the output sound volumes of the sound outputting apparatus, which are outputting sound, to fade out to the level 0 at the same time.

It is to be noted that, while the description above is given taking a case in which the master knob NM is operated leftwardly as an example, also when the master knob NM is operated rightwardly in the sound volume balance non-maintaining state, namely, also in the case of the operation in the direction toward the sound volume maximum value, the sound volume setting of the individual sound volume setting regions FD1 to FD4 may be changed using the value which has a ratio equal to the ratio of the operation amount to an operable amount of the master knob NM, with respect to an operable amount of each of the individual sound volume setting regions.

Also in the case of the operation of the master knob NM in the rightward direction, after the sound volume set value of one of the individual sound volume setting regions FD1 to FD4 reaches “100” at an end point of the region, if the master knob NM is operated rightwardly further, then processing is carried out in the sound volume balance non-maintaining state.

In this instance, the range from the position of the master knob NM at present to the right end of the slide bar SLM is determined as the operable amount, namely, 100%, and the ratio of the actual operation amount in the rightward direction is determined. Then, the sound volume set value of each individual sound volume setting region is updated based on the ratio, and also the display is given so as to indicate this.

In particular, where the sound volume set value stored as control change point information of each of the individual sound volume setting regions upon transition to the sound volume balance non-maintaining state is represented by “VLc” and the ratio of the operation amount of the master knob NM to the operable amount is represented by “R,” the new sound volume set value VLn of the individual sound volume setting region may be set to

VLn=VLc+(VLmax—VLc)×R.

where VLmax is the maximum sound volume set value, which is, in the case of the present example, “100.”

The ratio R is given, using the set value VMc of the master sound volume setting region FDM stored as the control change point information and the set value VMn of the master sound volume setting region FDM after the operation of the master knob NM, by

R=(VMn−VMc)/(100−VMc).

It is to be noted that VLc may be defined as the sound volume set value immediately before the operation of the master knob NM of the individual sound volume setting region and also VMn may be defined as the set value of the master sound volume setting region FDM immediately before the operation of the master knob NM.

In such an operation in the rightward direction, namely, in the direction toward the sound volume level 100, as described above, the sound volume setting of each individual sound volume setting region is changed using the value (VLmax−VLc)×R where VLmax−VLc is the operable amount of each individual sound volume setting region and which has a ratio equal to the ratio R of the operation amount of the master knob NM with respect to an operable amount of each of the individual sound volume setting region.

In this manner, after the sound volume balance is lost by the operation of the master knob NM in the rightward direction, the state in which the sound volume of all of the sound outputting apparatus is 100 can be established by an operation of the master knob NM by changing not the operation step number itself of the master knob NM but the sound volume set value of the individual sound volume setting regions FD1 to FD4 in response to the operation ratio of the master knob NM. Accordingly, if the user touches the master knob NM with a finger and moves the master knob NM to the right end portion, then it is possible to collectively and gradually increase the output sound volume of all of the remaining sound outputting apparatus, whose output does not reach a maximum output, to the maximum level until the maximum sound output level is reached simultaneously.

In the sound volume balance non-maintaining state, the sound volume set value of each individual sound volume setting region, on which an end point is not reached as yet, is increased or decreased in response to the operation ratio of the master knob NM as described above.

The processing in the sound volume balance non-maintaining state continues until a set value stored as the control change point information is reached.

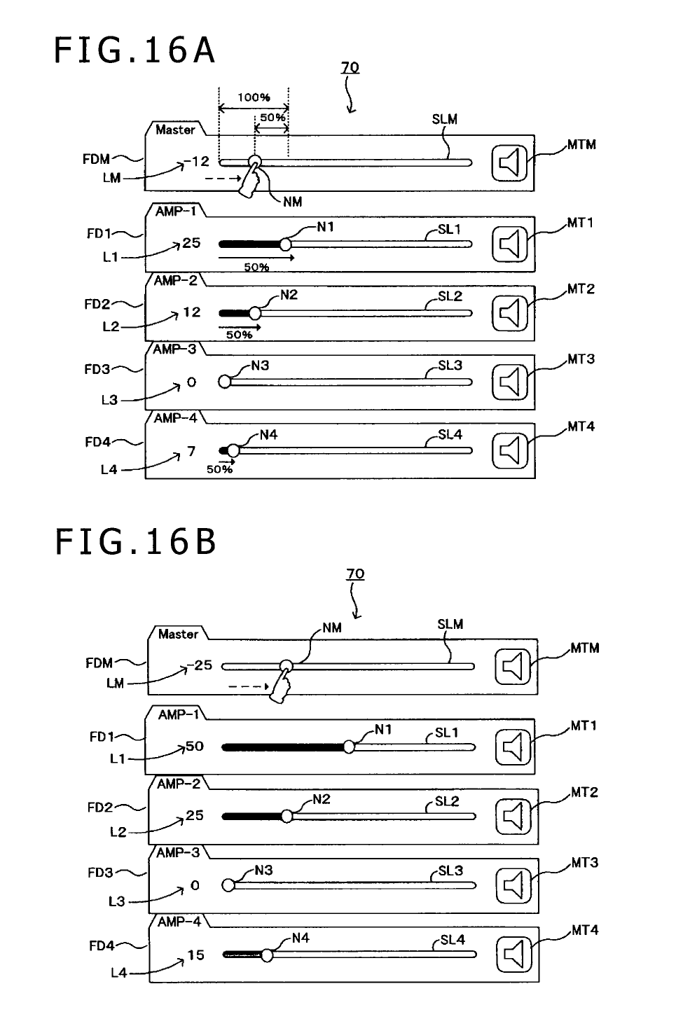

For example, it is assumed that, after the master knob NM is operated once to the left end as seen in FIG. 15B, the master knob NM is moved in the rightward direction to the position of 50% of the set value stored as the control change point information as seen in FIG. 16A.

Also in this instance, the sound volume set value of each individual sound volume setting region is increased or decreased in accordance with VLn=VLc×R given hereinabove in response to the ratio R of the master knob NM similarly as in the case described hereinabove. In particular, the sound volume set value of the individual sound volume setting region FD1 is set to “25” which is 50% of the sound volume set value stored in the control change point information. Similarly, the sound volume set values of the individual sound volume setting regions FD2 and FD4 are set to “12” and “7,” respectively. Then, this state is displayed as seen in FIG. 16A, and control information for the instruction of the sound volume set values is transmitted to the sound outputting apparatus. The sound volume set value of the individual sound volume setting region FD3 remains “0.”

Further, also in the case where the master knob NM is operated to the set value “−25” stored as the control change point information, the sound volume set values of the individual sound volume setting regions FD1 to FD4 are similarly set to “50,” “25,” “0” and “15” as seen in FIG. 16B.

In this manner, in the sound volume balance non-maintaining state, the sound volume set values of the individual sound volume setting regions FD1 to FD4 are controlled in response to the operation ratio of the master knob NM. Accordingly, at the point of time at which the master knob NM is operated rightwardly until the sound volume set value comes, after the master knob NM is operated in the sound volume balance non-maintaining state as in the case described hereinabove with reference to FIG. 15, to the set value when the sound volume balance non-maintaining state is reached, namely, at the point of time of FIG. 16B, the sound volume balance among the individual sound volume setting regions FD1 to FD4 returns to the sound volume balance upon transition to the sound volume balance non-maintaining state.

If the master knob NM is thereafter operated rightwardly further, then the control section 41 enters a sound volume balance maintaining state and carries out processing described in FIGS. 7A to 8B.

It is to be noted that, also after a certain individual sound volume setting region reaches an end point of the set value “100” and an operation is carried out in the sound volume balance non-maintaining state, a similar operation is carried out. In particular, at a point of time at which the master knob NM is operated leftwardly and then returns to the set value stored in the control change point information, the sound volume balance state of the sound outputting apparatus is restored. If the master knob NM is thereafter operated leftwardly further, then the control section 41 carries out the process described hereinabove with reference to FIGS. 7A to 8B in the sound volume balance maintaining state.

As described above, if an end point of a certain one of the individual sound volume setting regions FD1 to FD4 is reached by an operation of the master knob NM, then in response to a later operation of the master knob NM in the same direction, namely, in the direction of the operation by which the end portion is reached, processing is carried out in the sound volume balance non-maintaining state. Further, if, in a procedure of the operation of the master knob NM in the sound volume balance non-maintaining state, the master knob NM returns to a state same as that when the end point is reached and then is further operated in the same direction, namely, in the direction in which the master knob NM returns to the position, then processing is carried out in the sound volume balance maintaining state.

By such a process as described above, within a range within which the sound volume balance can be maintained, a collection operation by the master knob NM is a collection operation in a direction in which the sound volume balance is maintained. On the other hand, an operation of any of the individual sound volume setting regions FD1 to FD4 in the same direction after an end point thereof is reached is a collective operation even if the sound volume balance is lost. Further, even if the sound volume balance is lost once, the state of the sound volume balance can be restored by an operation of the master knob NM.

Consequently, the user can carry out an operation of the master knob NM to execute a desired collective operation without feeling a stress.

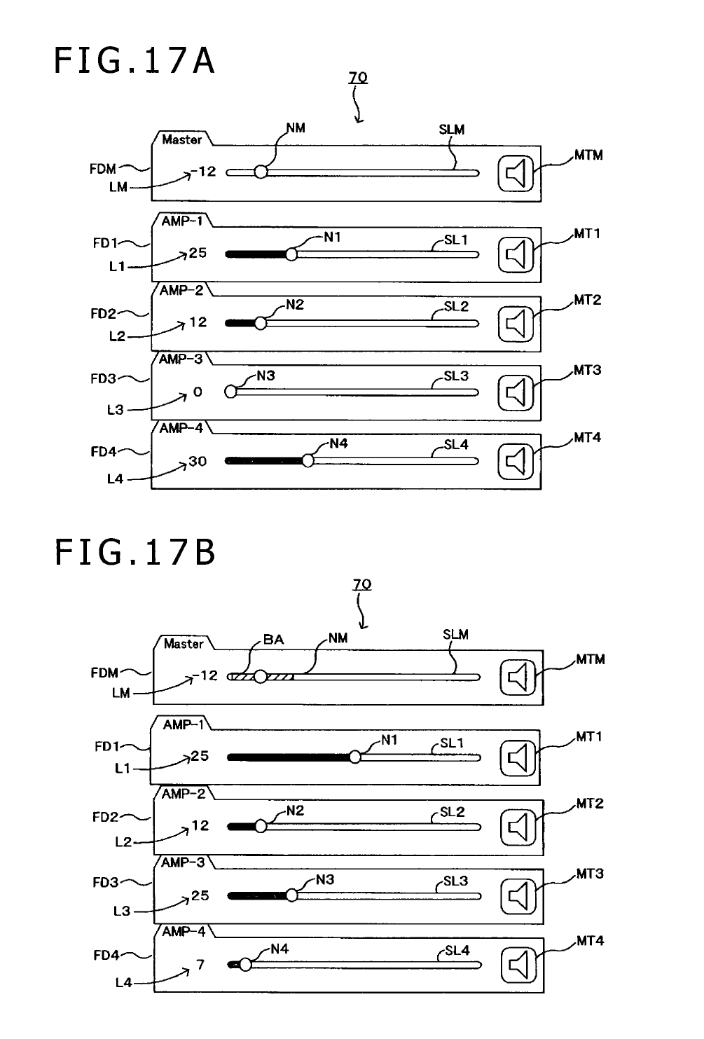

Incidentally, a case in which the user operates one of the individual sound volume setting regions FD1 to FD4 in the sound volume balance non-maintaining state is described with reference to FIGS. 17A and 17B. It is to be noted that operation described below with reference to FIGS. 17A and 17B is carried out similarly also in the case where a sound volume operation is carried out on the sound outputting apparatus side and information of the sound volume set value of the sound outputting apparatus is received by the remote controller 3.

FIG. 17A illustrates a case in which the user moves the knob N4 of the individual sound volume setting region FD4 rightwardly after the state of FIG. 15A is established after FIG. 14A. It is assumed that the sound volume set value is, for example, “30.”

The operation of FIG. 15A is that after an end point of the individual sound volume setting region FD3 is reached and a sound volume balance non-maintaining state is entered, and FIG. 17A illustrates an example in the case where an individual sound volume setting region other than the individual sound volume setting region FD3 on which an end point is reached is operated.

In this instance, the control section 41 updates the sound volume set value of the individual sound volume setting region FD4 from within the control change point information stored when the sound volume balance non-maintaining state is entered.

In particular, the set value of the master sound volume setting region FDM and the set values of the individual sound volume setting regions FD1 to FD4 at a point of time after the operation of the knob N4 of FIG. 17A may be updated as new control change point information. In other words, the control change point information may be updated considering that an end point of only the individual sound volume setting region FD3 is reached at this point of time. Thereafter, if the master knob NM is operated in the leftward direction, then the process in the sound volume balance non-maintaining state may be carried out similarly using the new control change point information.

In this manner, if an operation for an individual sound volume setting region other than that individual sound volume setting region, whose end point has been reached, and having triggered the transition to the sound volume balance non-maintaining state is detected in the sound volume balance non-maintaining state, then the control section 41 updates the control change point information. Consequently, from the state after the operation, a process in the sound volume balance non-maintaining state or transition into a sound volume balance maintaining state can be carried out similarly.

Now, a case in which an individual sound volume setting region whose end point has been reached and which has triggered the transition into the sound volume balance non-maintaining state is operated in the sound volume balance non-maintaining state is described with reference to FIG. 17B.

FIG. 17B illustrates a case in which the user moves the knob N3 of the individual sound volume setting region FD3 in the rightward direction after the state of FIG. 15A is established after FIG. 14A. In this instance, for example, the sound volume set value changes from “0” to “25.”

In this instance, the control section 41 erases the control change point information stored therein and enters a sound volume balance maintaining state.

In particular, FIG. 17B illustrates a state in which the sound volume set value of that one of the individual sound volume setting regions FD1 to FD4 whose sound volume set value has reached an end point does not exist at the end point any more. In this instance, the operation in the sound volume balance maintaining state described hereinabove with reference to FIGS. 7A to 8B may be carried out. In other words, a later operation of the master knob NM is carried out in a state in which the sound volume balance is maintained in the state after the operation of FIG. 17B.

In order to demonstrate to the user that the sound volume balance maintaining state is restored, also the balance operation range bar BA is displayed.

### <8. Example of a Process>

User operations, transmission of a control command and changeover of display using the sound volume operation display image 70 of the remote controller 3 are described above.

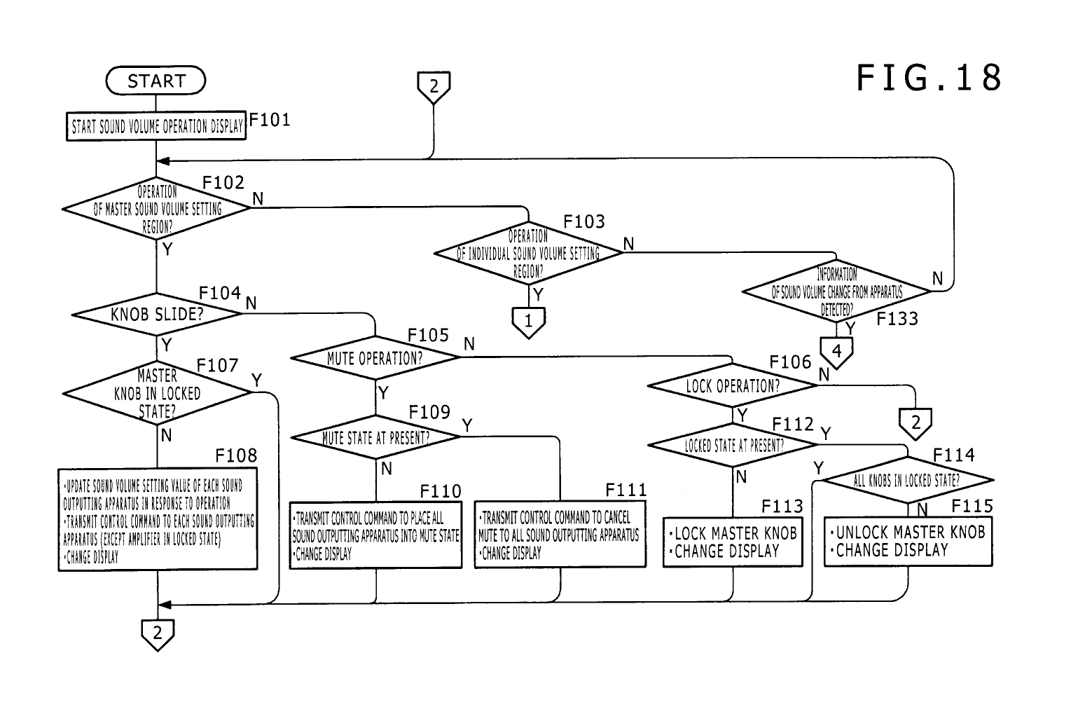

Here, an example of processing of the control section 41 of the remote controller 3 for implementing the operations described above is described with reference to FIGS. 18 to 22.

The process in FIGS. 18 to 22 illustrates an example of processing of the control section 41 when the sound volume operation display image 70 is displayed on the display section 45.

Referring first to FIG. 18, at step S101, display of the sound volume operation display image 70 is started on the display section 45 as seen in FIG. 6.

After the sound volume operation display image 70 is displayed at step F101, the control section 41 carries out monitoring of a touching operation of a user with the master sound volume setting region FDM or the individual sound volume setting regions FD1 to FD4 at steps F102 or F103.

Further, at step S133, the control section 41 monitors whether or not information of change of sound volume setting from the sound outputting apparatus, namely from the reproduction apparatus 1 and the network speakers 2B, 2C and 2D, is received by the transmission/reception section 43.

If a touching operation with the master sound volume setting region FDM is detected, then the control section 41 branches the processing in response to a type of the operation at steps F104, F105 and F106.

As described hereinabove, as an operation of the master sound volume setting region FDM, a sliding operation of the master knob NM, an operation of the mute button MTM and a locking operation, namely, a tapping operation of the master knob NM, are available.

If a sliding operation of the master knob NM is detected, then the control section 41 advances the processing from step F104 to step F107, at which it confirms whether or not the master knob NM is set to a locked state, namely, to an operation-inhibited state, at present.

If the master knob NM is in a locked state at present, then the control section 41 invalidates the sliding operation of the user detected in the present operation cycle and returns to the monitoring loop of steps F102, F103 and F133 without particularly carrying out a process for the operation.

If the master knob NM is not in a locked state at step F107, then the processing advances to step F108, at which the control section 41 carries out a process corresponding to the operation of the user.

First, the control section 41 updates the sound volume set value of the sound outputting apparatus in response to the sliding operation amount and direction. Then, the control section 41 transmits a control command for the instruction of the updated sound volume set value to each sound outputting apparatus, that is, each of the reproduction apparatus 1 and the network speakers 2B, 2C and 2D.

Further, the control section 41 carries out display change control in response to the sliding operation of the master knob NM. In particular, the control section 41 changes the knob position and the numerical value on the numerical value displaying region LM in accordance with the sliding movement of the master knob NM. Further, if the control section 41 is in the sound volume balance maintaining state, then it changes the display position of the balance operation range bar BA. Further, the control section 41 carries out movement of the positions of the knobs N1 to N4 on the individual sound volume setting regions FD1 to FD4 and change of the numerical values of the numerical value displaying regions L1 to L4 in response to the sliding movement of the master knob NM.

It is to be noted that, if any of the knobs N1 to N4 on the individual sound volume setting regions FD1 to FD4 is in a locked state, then a display change is not carried out with regard to the individual sound volume setting region which is in a locked state. Further, updating of the sound volume set value and transmission of a control command to the corresponding sound outputting apparatus are not carried out.

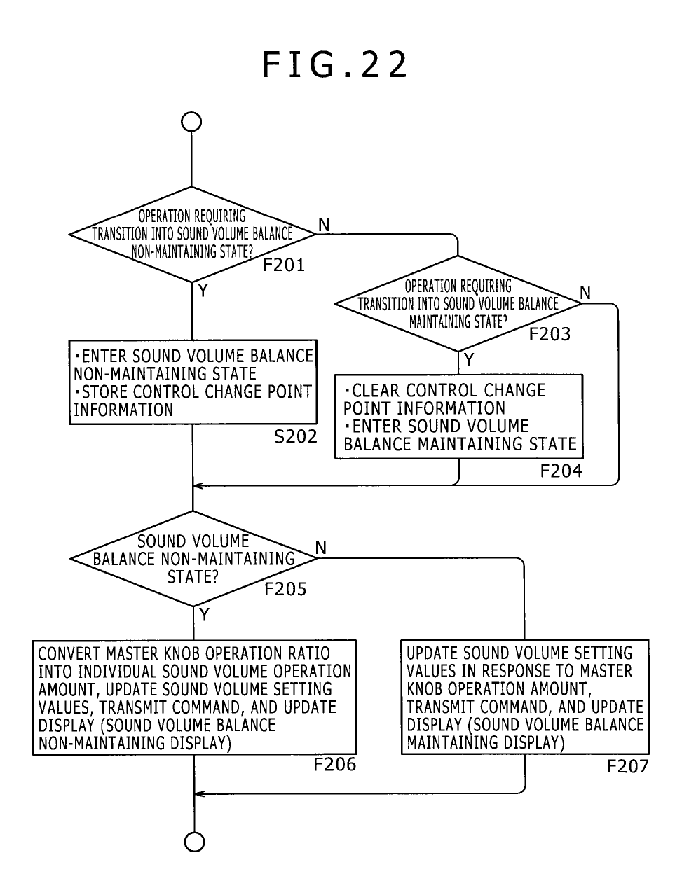

FIG. 22 illustrates an example of a particular process at step F108.

Referring to FIG. 22, the control section 41 first decides at step F201 whether or not the operation of the master knob NM detected in the present operation cycle requires transition into a sound volume balance non-maintaining state. In particular, the control section 41 confirms whether or not the operation is carried out in a direction same as that in which one of the individual sound volume setting regions FD1 to FD4 is operated until an end point is reached.

In such a case, the control section 41 enters, at step F202, a sound volume balance non-maintaining state and stores a set value of the master sound value setting region and sound value set values of the individual sound volume setting regions FD1 to FD4 at a point of time before the operation in the present operation cycle as control change point information.

If the operation of the master knob NM detected in the present operation cycle does not require transition into a sound volume balance non-maintaining state at step F201, then the processing advances from step F201 to step F203. At step F203, the control section 41 decides whether or not the operation of the master knob NM detected in the present operation cycle requires transition into a sound volume balance maintaining state.

In other words, it is detected whether or not the operation is carried out in a direction same as that when the sound volume set value of the relevant one of the individual sound volume setting regions FD1 to FD4 returns to the value stored as the control change point information.

In such an instance, at step F204, the control section 41 enters a sound volume balance maintaining state and clears the control change point information which has been stored therein.

An affirmative decision is not made at any of steps F201 and F203 in a case in which processing is to be continued in a sound volume balance maintaining state and in another case in which processing is to be continued in a sound volume balance non-maintaining state.

At step F205, the control section 41 branches the processing depending upon whether or not the state at present is the sound volume balance non-maintaining state.

In the case where the state at present is the sound volume balance maintaining state and the processing is being continued, or when the sound volume balance maintaining state is entered at step F204, the control section 41 advances the processing to step F207.

In this instance, the control section 41 uses a value corresponding to the operation amount itself of the master knob NM to change the sound volume set value of each individual sound volume setting region and generates a control signal for the instruction of the new sound volume setting. Then, the control section 41 causes the transmission/reception section 43 to transmit and output the control signal to each sound outputting apparatus, namely, to each of the reproduction apparatus 1 and the network speakers 2B, 2C and 2D.

Further, the control section 41 carries out display change control in response to the sliding operation of the master knob NM. In particular, the control section 41 carries out change of the knob position and the numerical value on the numerical value displaying region LM in response to the sliding movement of the master knob NM. Further, the control section 41 carries out movement of the positions of the knobs N1 to N4 and change of the numerical values on the numerical value displaying regions L1 to L4 based on the new sound volume set values of the individual sound volume setting regions FD1 to FD4. Further, the control section 41 carries out display of the balance operation range bar BA in response to the position of the master knob NM at the point of time.

In particular, a process of the operation described hereinabove with reference to FIGS. 7A to 8B is carried out.

On the other hand, if the state at present is the sound volume balance non-maintaining state and the process is being continued at step F205 or when the sound volume balance non-maintaining state is entered into the processing at step F202, then the control section 41 advances the processing from step F205 to step F206.

In this instance, the control section 41 uses values of the individual sound volume setting regions FD1 to FD4 with respect to the operable amount which exhibit a ratio equal to that of the operation amount of the master knob NM to change the sound volume setting of the individual sound volume setting regions FD1 to FD4. Then, the control section 41 generates a control signal for the instruction of the new sound volume setting and controls the transmission/reception section 43 to transmit and output the control signal to each of the sound outputting apparatus, namely, to each of the reproduction apparatus 1 and the network speakers 2B, 2C and 2D.

Further, the control section 41 carries out display change control in response to the sliding operation of the master knob NM. In other words, the control section 41 carries out change of the knob position and the numerical value on the numerical value displaying region LM in response to the sliding movement of the master knob NM. Furthermore, the control section 41 carries out movement of the positions of the knobs N1 to N4 and change of the numerical values on the numerical value displaying regions L1 to L4 based on the new sound volume set values of the individual sound volume setting regions FD1 to FD4.

Display of the balance operation range bar BA is not executed. This is intended to indicate the sound volume balance non-maintaining state.

In other words, the process of the operation described hereinabove with reference to FIGS. 14A to 15B is carried out.

When the master knob NM is slid, the control section 41 carries out the process described hereinabove with reference to FIG. 22 at step F108 of FIG. 18 and then returns the processing to the monitoring loop of steps F102, F103 and F133.

If the control section 41 detects a tapping operation of the mute button MTM by the user at step F105, then the control section 41 advances the processing from step F105 to step F109. At step F109, the control section 41 confirms whether or not the mute button MTM indicates a mute state, or in other words, whether or not all sound outputting apparatus are placed in a mute state.

If all sound outputting apparatus are not in a mute state at present, then the tapping operation of the user detected in the present operation cycle is recognized as a mute operation, and the control section 41 carries out a muting process at step F110. In particular, the control section 41 transmits a control command for the instruction of a mute state to each sound outputting apparatus, namely, to each of the reproduction apparatus 1 and the network speakers 2B, 2C and 2D. It is to be noted that, if some sound outputting apparatus is already placed in a mute state, then the mute command to the sound outputting apparatus need not be transmitted.

Further, the control section 41 carries out display change control of the mute buttons MTM and MT1 to MT4. In particular, the control section 41 changes the display image of the mute buttons MTM and MT1 to MT4 to such a display image which represents a mute state as seen in FIG. 13B.

After the control section 41 carries out such a muting process as described above at step F110, it returns the processing to the monitoring loop of steps F102, F103 and F133.

On the other hand, if the control section 41 determines at step F109 that the state at present is a mute state, then it recognizes that the tapping operation of the user detected in the present operation cycle is a mute canceling operation and carries out a mute canceling operation at step F111.

In particular, the control section 41 transmits a control command for the mute cancellation to the sound outputting apparatus, namely, to the reproduction apparatus 1 and the network speakers 2B, 2C and 2D.

Further, the control section 41 carries out display change control of the mute buttons MTM and MT1 to MT4. In particular, the control section 41 controls so that the display of the mute buttons MTM and MT1 to MT4 is returned from the state of FIG. 13B to such an ordinary state as seen in FIG. 7B.

After the control section 41 carries out such a mute canceling process as described above at step F111, it returns the processing to the monitoring loop of steps F102, F103 and F133.

If the control section 41 detects a locking operation of the user, namely, a tapping operation of the master knob NM at step F106, then it advances the processing from step F106 to step F112, at which it confirms whether or not the master knob NM is in a locked state, namely, in an operation inhibition state, at present.

If the master knob NM is not in a locked state, then the control section 41 recognizes that the tapping operation of the user detected in the present operation cycle is a locking operation and carries out a locking process of the master knob NM at step F113. In particular, the control section 41 inhibits a sliding operation of the master knob NM. Further, the control section 41 causes the master knob NM to be displayed as a display image in a locked state, and further controls so that the numerical value displaying region LM is displayed in display image of an inactive state to demonstrate to the user that the master knob NM is in a locked state.

Then, the control section 41 returns the processing to the monitoring loop of steps F102, F103 and F133.

By placing the master knob NM into a locked state in this manner at step F113, even if a sliding operation of the master knob NM is detected thereafter, the operation is invalidated at step F107 described hereinabove.

On the other hand, if the control section 41 determines at step F112 that the master knob NM is in a locked state at present, then it recognizes that the tapping operation of the user detected in the present operation cycle is a lock canceling operation and advances the processing to step F114. At step F114, the control section 41 determines whether or not all of the knobs N1 to N4 of the individual sound volume setting regions FD1 to FD4 are in a locked state.

In the present embodiment, when all of the knobs N1 to N4 are in a locked state, also the master knob NM is controlled to a locked state. Conversely speaking, when all of the knobs N1 to N4 are placed into a locked state, the master knob NM is automatically placed into a locked state.

From this, when all of the knobs N1 to N4 are in a locked state, even if a lock canceling operation is carried out for the master knob NM, the locked state of the master knob NM is not canceled.

Therefore, when all of the knobs N1 to N4 are in a locked state at step F114, also a lock canceling operation for the master knob NM is invalidated, and the processing returns to the monitoring loop of steps F102, F103 and F133.

On the other hand, if it is found at step F114 that at least one of the knobs N1 to N4 is not in a locked state, then also the master knob NM accepts unlocking operation. Therefore, the control section 41 advances the processing to step F115, at which it carries out an unlocking process. In particular, the control section 41 cancels the inhibition state of sliding operation of the master knob NM. Further, the control section 41 carries out control to return the display of the master knob NM and the numerical value displaying region LM to their ordinary display to present the unlocking to the user. Then, the control section 41 returns the processing to the monitoring loop of steps F102, F103 and F133.

The foregoing is a process executed when an operation of the master sound volume setting region FDM is detected.

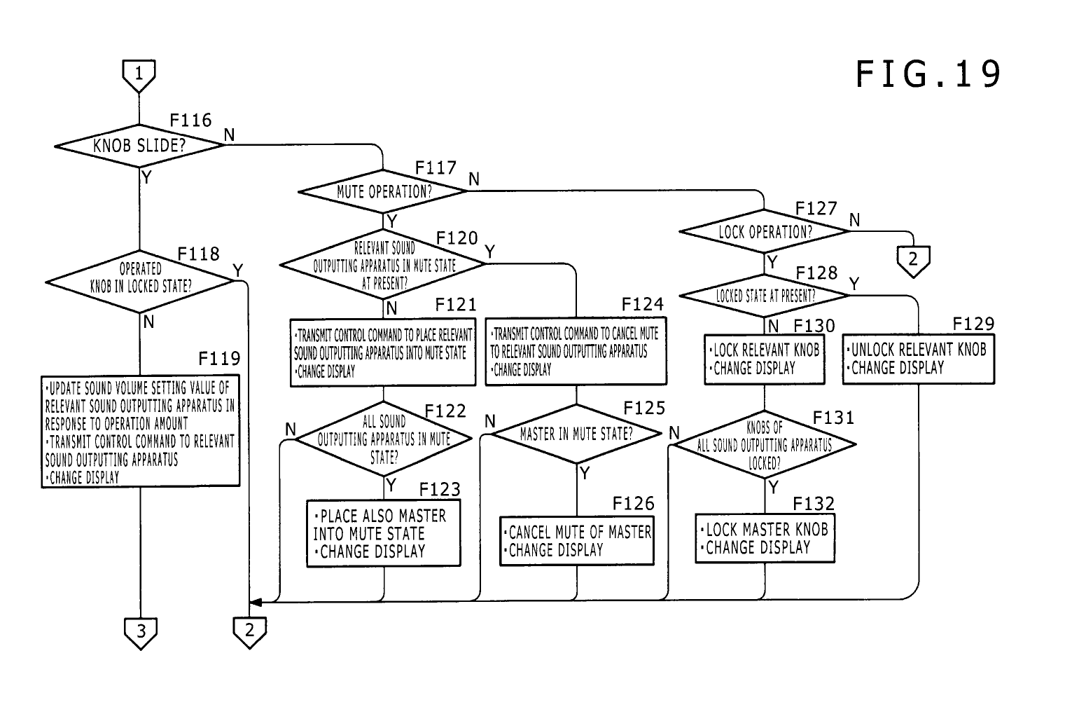

If the operation of the user is an operation for any of the individual sound volume setting regions FD1 to FD4, the processing of the control section 41 advances from step F103 to the process of FIG. 19, in which the control section 41 branches the processing at steps F116, F117 and F127 according to the type of the operation.

As described above, as the operation for the individual sound volume setting regions FD1 to FD4, a sliding operation of the knobs N1 to N4, an operation of the mute buttons MT1 to MT4 and a locking operation, which is a tapping operation, of the knobs N1 to N4 are available.

It is to be noted that, in the following description, x represents one of “1” to “4,” and for example, Nx represents the operated one of the knobs N1 to N4, Lx one of numerical value displaying regions L1 to L4, and MTx the operated one of the mute buttons MT1 to MT4.

If the control section 41 detects a sliding operation of the knob Nx by the user, it advances the processing from step F116 to step F118, at which it confirms whether or not the operated knob Nx is in a locked state, namely, in an operation-inhibited state.

If the knob Nx is in a locked state at the present time, it invalidates the sliding operation by the user detected at that time and returns the processing to the monitoring loop of steps F102, F103 and F133 without particularly carrying out a process in response to the operation.

On the other hand, if the knob Nx that has been slid is not in a locked state, the control section 41 advances the processing to step F119, at which it carries out a process corresponding to the operation by the user.

First, the control section 41 updates the sound volume set value of the corresponding sound outputting apparatus according to the amount and direction of the sliding operation. Then, the control section 41 transmits a control command to indicate the updated sound volume set value to the sound outputting apparatus, which is one of the reproduction apparatus 1 and the network speakers 2B, 2C and 2D.

Further, the control section 41 carries out display change control in response to the sliding operation of the knob Nx. In particular, the control section 41 changes the knob position and the numerical value of the numerical value displaying region Lx according to the sliding operation of the knob Nx.

Further, when the control section 41 is in the sound volume balance maintaining state, movement of the knob Nx sometimes results in change of the range of the balance operation range bar BA and the position of the master knob NM on the master sound volume setting region FDM as described hereinabove with reference to FIGS. 11A and 11B. In that case, the control section 41 carries out also display change control of the balance operation range bar BA and the master knob NM.

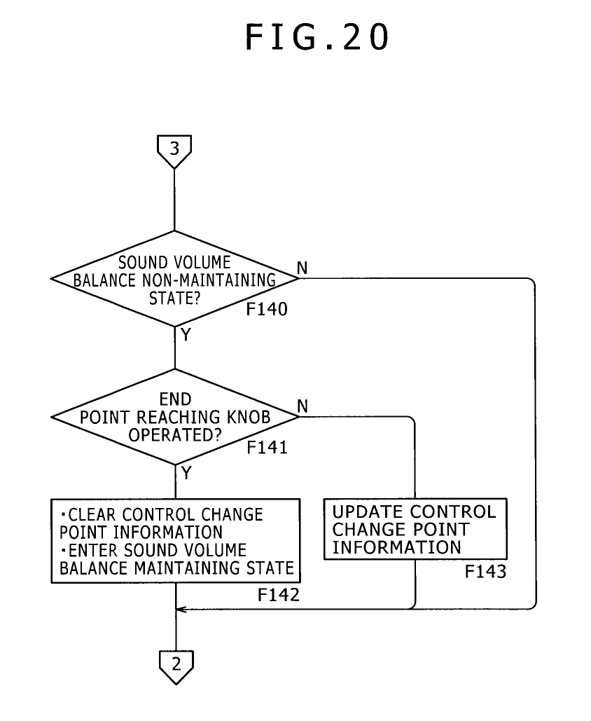

Upon sliding operation of the knob Nx, after the process at step F119 is carried out, the control section 41 advances the processing to step F140 illustrated in FIG. 20.

At step F140, the control section 41 confirms whether or not it is in the sound volume balance non-maintaining state at present.

If the control section 41 is not in the sound volume balance non-maintaining state but in the sound volume balance maintaining state, then it ends the process of FIG. 20 immediately and returns the processing to the monitoring loop of steps F102, F103 and F133 of FIG. 18.

On the other hand, if the control section 41 is in the sound volume balance non-maintaining state at the present time, then it confirms at step F141 whether or not the knob Nx operated at that time is the end point reaching knob which triggered the transition to the sound volume balance non-maintaining state.

If the operated knob Nx is the end point reaching knob, then the control section 41 advances the processing to step F142, at which the state is shifted to the sound volume balance maintaining state and the control change point information stored upon transition to the sound volume balance non-maintaining state is cleared. In other words, the control section 41 carries out the process described earlier with reference to FIG. 17B. The control section 41 then returns the processing to the monitoring loop of steps F102, F103 and F133 of FIG. 18.

On the other hand, if the operated knob Nx is a knob other than the end point reaching knob at step F141, the control section 41 advances the processing to step F143, at which it updates the control change point information. In particular, as the process described hereinabove with reference to FIG. 17A, the control section 41 sets the sound volume set values of the individual sound volume setting regions FD1 to FD4 after the operation and the set value of the master sound volume setting region as the new control change point information. Then, the control section 41 returns the processing to the monitoring loop of steps F102, F103 and F133 of FIG. 18.

When the operation of the user is an operation for any of the individual sound volume setting regions FD1 to FD4 and the control section 41 advances the processing to the process of FIG. 19, if the control section 41 detects a tapping operation of a mute button MTx by the user, then the control section 41 advances the processing from step F117 to step F120. At step F120, the control section 41 confirms whether or not the mute button MTx indicates a mute state, namely, whether or not the corresponding sound outputting apparatus is in a mute state.

If the mute button MTx does not indicate a mute state, the control section 41 recognizes that the tapping operation of the user detected at that time is a muting operation and carries out muting operation at step F121. In particular, the control section 41 transmits a control command to order muting to that one of the sound outputting apparatuses, namely, the reproduction apparatus 1 and the network speakers 2B, 2C and 2D, which corresponds to the mute button MTx.

Further, the control section 41 carries out display change control of the mute button MTx. In particular, the control section 41 changes the display image of the mute button MTx to a display image that indicates a mute state like the mute button MTx of FIG. 13A.

After the muting process for the certain sound outputting apparatus is carried out, the control section 41 confirms at step F122 whether or not all of the sound outputting apparatuses are in a mute state at the present point of time. In this example, it is assumed that, when all sound outputting apparatuses are placed into a mute state, also the mute button MTM of the master sound volume setting region FDM is automatically placed into a mute state. Thus, if all of the sound outputting apparatus are placed in a mute state, then the control section 41 advances the processing to step F123, at which it places also the mute button MTM of the master sound volume setting region FDM into a mute state. The mute buttons will be displayed as shown in FIG. 13B. Then, the control section 41 returns the processing to the monitoring loop of steps F102, F103 and F133.

On the other hand, if at least one of the sound outputting apparatus is not in a mute state at step F122, then the control section 41 returns the processing from step F122 to the monitoring loop of steps F102, F103 and F133 without carrying out a process for the mute button MTM on the master sound volume setting region FDM.

Meanwhile, if the control section 41 decides at step F120 that the sound outputting apparatus that corresponds to the operated mute button MTx is currently in a mute state, the control section 41 recognizes the tapping operation of the user detected at that time as a mute canceling operation and carries out a mute canceling operation at step F124.

In particular, the control section 41 transmits a control command for canceling the mute state to the sound outputting apparatus corresponding to the mute button MTx.

Further, the control section 41 controls the display of the mute button MTx and returns it to its ordinary state.

After the control section 41 carries out such a mute canceling process as described above at step F124, the control section 41 confirms the state of the mute button MTM on the master sound volume setting region FDM at step F125.

In this example, the mute button MTM on the master sound volume setting region FDM is placed into a mute state at step F123 or step F110. In other words, when a mute state of all sound outputting apparatus is established or when all sound outputting apparatus are to be placed into a mute state, also the mute button MTM of the master sound volume setting region FDM is placed into a mute state.

The mute state of the mute button MTM is canceled automatically when the mute state is canceled on any one of the individual sound volume setting regions FD1 to FD4.

Thus, if also the mute button MTM on the master sound volume setting region FDM indicates a mute state at step F125, the control section 41 carries out a process for canceling the mute state also of the mute button MTM on the master sound volume setting region FDM at step F126 in response to the cancelation of the mute state at step F124 of that time. Then, the control section 41 returns the processing to the monitoring loop of steps F102, F103 and F133.

Incidentally, if the mute button MTM of the master sound volume setting section FDM is not in a mute state at step F125, the control section 41 returns the processing directly from step F125 to the monitoring loop of steps F102, F103 and F133.

If the control section 41 detects a locking operation by the user, namely, a tapping operation of a knob Nx, the control section 41 advances the processing from step F127 to step F128, at which it confirms whether or not the knob Nx is currently in a locked state, namely, in an operation-inhibited state.

If the knob Nx is not in a locked state at the present time, the control section 41 recognizes that the tapping operation by the user detected at that time is a locking operation and carries out locking of the knob Nx at step F130. In particular, the control section 41 inhibits sliding operation of the knob Nx. Further, the control section 41 carries out control to change the display image of the knob Nx to a display image in a locked state and change the display image of the numerical value displaying region Lx to a display image of an inactive state to present the locked state to the user.

As mentioned earlier, in this example, when all of the knobs N1 to N4 are placed into a locked state, also the master knob NM is automatically placed into a locked state. Thus, the control section 41 decides at step F131 whether or not all of the knobs N1 to N4 of the individual sound volume setting regions FD1 to FD4 have been placed into a locked state by the lock process at step F130 of that time. If all of the knobs N1 to N4 have been placed into a locked state, then the control section 41 advances the processing to step F132, at which it places also the master knob NM into a locked state and carries out control to display the locked state of the master knob NM and the inactive state on the numerical value displaying region LM. Then, the control section 41 returns the processing to the monitoring loop of steps F102, F103 and F133.

If at least one of the knobs is not in a locked state at step F131, the control section 41 returns the processing to the monitoring loop of steps F102, F103 and F133 without carrying out the process at step F132.

On the other hand, if the control section 41 decides at step F128 that the knob Nx is currently in a locked state, then it recognizes that the tapping operation of the user detected at that time is an unlocking operation and advances the processing to step F129. At step F129, the control section 41 cancels the inhibited state of the sliding operation of the knob Nx. Further, the control section 41 carries out control to return the display of the knob Nx and the numerical value displaying region Lx to their ordinary display to present the unlocking to the user. Then, the control section 41 returns the processing to the monitoring loop of steps F102, F103 and F133.

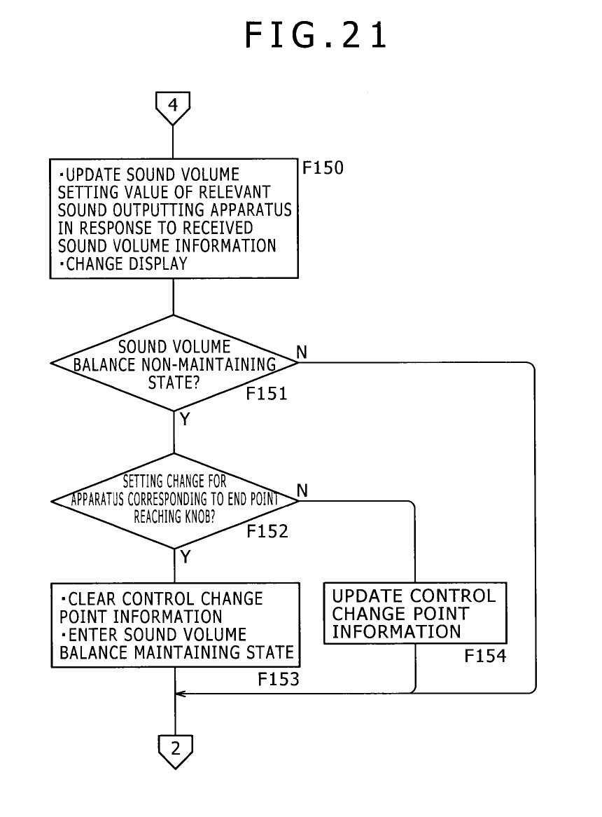

If the control section 41 detects at step F133 in FIG. 18 that information on a change in sound volume setting is received from a certain sound outputting apparatus, it carries out the process of FIG. 21. This is a case where one of the reproduction apparatus 1 and the network speakers 2B, 2C and 2D is operated on the apparatus side to change sound volume.

In this case, the control section 41 updates the sound volume set value of the corresponding sound outputting apparatus, namely, the sound volume set value of the sound volume setting region FDx corresponding to the sound outputting apparatus according to the received information on the sound volume setting. Then, the control section 41 changes the display accordingly. In short, the control section 41 changes the position of the knob Nx and the numerical value of the numerical value displaying region Lx according to the new sound volume set value.

Then, the control section 41 confirms at step F151 whether or not it is currently in a sound volume balance non-maintaining state.

If the control section 41 is not in a sound volume balance non-maintaining state but in a sound volume balance maintaining state, it ends the process of FIG. 21 immediately and returns the processing to the monitoring loop of steps F102, F103 and F133 in FIG. 18.

If the control section 41 is currently in a sound volume balance non-maintaining state, then it confirms at step F152 whether or not the sound outputting apparatus whose sound volume setting has been changed this time is the one corresponding to the individual sound volume setting region FDx whose knob is the end point reaching knob that triggered the transition to the sound volume balance non-maintaining state.

If the sound outputting apparatus is the one corresponding to the end point reaching knob, the control section 41 advances the processing to step F153. At step F153, the state is shifted to the sound volume balance maintaining state and the control change point information stored when it was shifted to the sound volume balance non-maintaining state is cleared. In other words, the control section 41 carries out the process described hereinabove with reference to FIG. 17B. Then, the control section 41 returns the processing to the monitoring loop of steps F102, F103 and F133 of FIG. 18.

On the other hand, if the sound outputting apparatus whose sound volume setting has been changed is not the one corresponding to the individual sound volume setting region FDx of the end point reaching knob, then the control section 41 advances the processing to step F154, at which it updates the control change point information. In other words, as the process described hereinabove with reference to FIG. 17A, the sound volume set values of the individual sound volume setting regions FD1 to FD4 after the change and the set value of the master sound volume setting region are set as the new control change point information. The control section 41 then returns the processing to the monitoring loop of steps F102, F103 and F133 of FIG. 18.

As the control section 41 of the remote controller 3 carries out the processes of FIGS. 18 to 22, the transmission of control commands and display controlling corresponding to such operations by the user as touching, described with reference to FIGS. 16 and 17, are executed.

With such an embodiment as described above, the user can carry out the following operations using the remote controller 3.

First, the output sound volume of a plurality of sound outputting apparatus in a home network system, here the reproduction apparatus 1 and the network speakers 2B, 2C and 2D, in other words, the sound volume in the rooms A, B, C and D, can be controlled individually. This can be done by operating the knobs N1 to N4 of the individual sound volume setting regions FD1 to FD4.

Further, the sound volume operations of the sound outputting apparatus can be inhibited or permitted by a locking operation or an unlocking operation individually for the knobs N1 to N4.

It is possible to temporarily stop sound output or cancel the mute state with the mute buttons MT1 to MT4 while maintaining the sound volume setting of each sound outputting apparatus.

Operating the master knob NM, it is possible to collectively control the sound volume settings of the sound outputting apparatuses while maintaining the sound volume balance of the sound outputting apparatuses.

Even in a region in which the sound volume balance cannot be maintained, the sound volume can be controlled collectively by operating the master knob NM. For example, collective fade-out, fade-in, increasing of the sound levels to their maximum levels and so forth can be carried out.

Further, even if the state once becomes a sound volume balance non-maintaining state, the original sound volume balance maintaining state can be restored unless the individual sound volume setting regions FD1 to FD4 are operated, namely, unless the user intentionally changes the sound volume balance. Therefore, the user can operate the master knob NM without being strongly aware of maintaining the sound volume balance.

It is possible to collectively place all of the sound outputting apparatus into a mute state or cancel the mute state by operating the mute button MTM of the master sound volume setting region FDM.

Further, the user can confirm the state of the sound volume setting of the sound outputting apparatus anytime from the sound volume operation display image 70.

The user can readily recognize the sound volume balance maintaining state and the sound volume balance non-maintaining state from the display of the balance operation range bar BA. Further, in the sound volume balance maintaining state, the user can recognize the range of operation of the master knob NM within which the balance can be maintained from the balance operation range bar BA. This is therefore also preferable in the case where the user is to carry out an operation thinking of maintaining the sound volume balance.

In the present embodiment, the operations and confirmation are facilitated without using a sound mixing console which is used in a PA system or the like.

### <9. Modifications and Program>

The examples of processes exemplified in FIGS. 6 to 17B and described in FIGS. 18 to 22 are mere examples, and, for example, such various modifications as described below are available.

In the example described hereinabove, the control section 41 controls the display section 45 to display different display forms between the sound volume balance maintaining state and the sound volume balance non-maintaining state as presence or absence of a display image of the balance operation range bar BA. In addition to this, various display manners for allowing a user to recognize maintenance/non-maintenance of the balance are possible. For example, the color of the master sound volume setting region FDM or the slide bar SLM may be varied, or a mark, a character or the like indicative of a balanced state or a non-balanced state may be displayed. In any case, it suffices if the user can distinguish the sound volume balance maintaining state and the sound volume balance non-maintaining state from each other.

Further, as regards a locking operation of the master knob NM, locking of the knobs N1 to N4 may be interlocked with the locking operation.

In particular, at step F113 of FIG. 18, not only the master knob NM but also all of the knobs N1 to N4 may be collectively brought into a locked state.

The decision at step F114 may be omitted, and at step F115, all of the knobs N1 to N4 may be unlocked in response to and concurrently with the unlocking of the master knob NM.

Configuring the locking system as above, collective locking/unlocking can be carried out conveniently by locking/unlocking the master knob NM.

Further, at step F129 of FIG. 19, if a certain knob Nx is unlocked and resultantly all of the knobs N1 to N4 are placed into the unlocked state while the master knob NM is in a locked state, then also the master knob NM may be unlocked automatically.

In the locked state of the master knob NM and the knobs N1 to N4, not only the operation of the knob but also operation of the corresponding one of the mute buttons MTM and MT1 to MT4 may be inhibited. In that case, such a display example is possible that indicates that the corresponding one of the master sound volume setting region FDM and the individual sound volume setting regions FD1 to FD4 is entirely inactive.

The numerical value displaying region LM of the master sound volume setting region FDM may display, as an intermediate value Vttl between the values Vmax and Vmin which are, respectively, the maximum sound volume setting and the minimum sound volume setting of the individual sound volume setting regions FD1 to FD4 to be controlled. The intermediate value Vttl can be calculated by the following expression.

Vtt1=(Vmax+Vmin)/2

On the master sound volume setting region FDM and the individual sound volume setting regions FD1 to FD4 of the above example, the master knob NM and the knobs N1 to N4 are slid left and right to operate the sound volume setting. Alternatively, it may be operated by sliding up and down, or a different display form may be used, for example, a dial-like image which the user operates by rotating it.

Naturally, the sound volume operation display image 70 may be designed in various forms and its operation elements may take various forms as well. They differ depending on the number and type of sound outputting apparatuses on the network 4.

While the controlling terminal apparatus of the above-described embodiment transits between the sound volume balance maintaining state and the sound volume balance non-maintaining state, a controlling terminal apparatus that always operates in the sound volume balance non-maintaining state is also possible.

Specifically, the control section 41 always carries out a process that changes the sound volume settings of the individual sound volume setting regions FD1 to FD4 using such a value that the ratio between the value and the operable amount of the operated one of individual sound volume setting regions FD1 to FD4 is the same as that between the operation amount and the operable amount of the master sound volume setting region FDM. Then, a control signal for indicating the new sound volume setting is generated, and transmitted from the transmission/reception section 43 to the sound outputting apparatus.

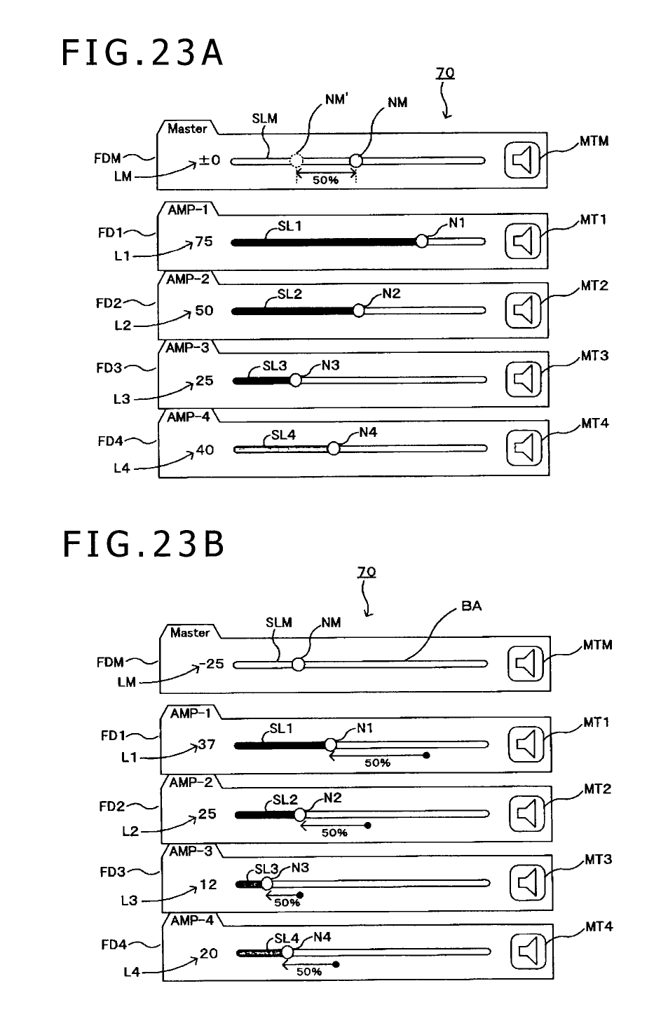

FIGS. 23A and 23B illustrate an example of this case. For example, it is assumed that the master knob NM is operated leftward by 50% to a position of a master knob NM′ indicated by a broken line as shown in FIG. 23A. The sound volume set values of the individual sound volume setting regions FD1 to FD4 are here assumed to be “75,” “50,” “25” and “40,” respectively.

In this case, the sound volume set values of the individual sound volume setting regions FD1 to FD4 are changed by 50%. In particular, the sound volume set values of the individual sound volume setting regions FD1 to FD4 are changed to “37,” “25,” “12” and “20,” respectively, and control signals for indicating these values are transmitted to the sound outputting apparatuses. As regards the display state, as shown in FIG. 23B, the knobs N1 to N4 are moved to positions corresponding to the operation amount of 50%, and the values of the numerical value displaying regions L1 to L4 are changed.

On condition that the sound volume balance need not to be always maintained, the process of the sound volume balance non-maintaining state described earlier may always be applied as above.

Naturally, it may be configured such that a user can arbitrarily select the operation mode between a mode in which the sound volume balance maintaining state and the sound volume balance non-maintaining state are switched and a mode in which the state is always the sound volume balance non-maintaining state.

Further, while the embodiment described above was an example of application of the technology of the present disclosure to a distribution system of music content, the technology of the present disclosure can also be applied to other systems.

For example, an apparatus similar to the remote controller 3 in the present embodiment may be used as a controlling terminal apparatus of a system which carries out distribution and synchronous reproduction of video content, text or game data as a home network.

In addition to content distribution systems, the technology of the present disclosure can be applied to the controlling of electronic apparatuses connected via a network. For example, the technology of the present disclosure may be applied to a controlling terminal apparatus of a system in which a plurality of apparatuses such as a television receiver, monitor display and information apparatus are connected to each other via a network.

Furthermore, the application of the technology of the present disclosure is not limited to a network-connected system. For example, the technology of the present disclosure may be applied to a controlling terminal apparatus such as a remote controller that can directly transmit control commands to a plurality of sound outputting apparatuses by infrared, radio or wire communication.

The program of the embodiment is a program that causes an arithmetic processing unit such as a CPU or DSU (Digital Signal Processor) execute a process in the sound volume balance non-maintaining state described hereinabove.

In particular, the program causes the arithmetic processing unit execute a process to display, on the display section, individual sound volume setting regions of the sound outputting apparatuses which each includes the sound volume setting and operation elements with which the sound volume setting can be varied, and a master sound volume setting region which includes operation elements with which the sound volume settings of the plurality of sound outputting apparatuses can be varied simultaneously.

When an operation for the master sound volume setting section is detected by the operation detection section, the program causes the arithmetic processing unit execute a process that changes the sound volume setting of each of the individual sound volume setting regions using such a value that the ratio between the value and the operable amount of the individual sound volume setting region is equal to that between the detected operation amount and the operable amount of the master sound setting section upon the operation.

Further, the program causes the arithmetic processing unit execute a process that generates control signals for indicating the new sound volume settings and transmits them from the transmission section to the sound outputting apparatuses.

Specifically, the program of the embodiment may be a program that causes an arithmetic processing unit execute the processes described with reference to FIGS. 18 to 22.

An apparatus which executes the sound volume control described hereinabove can be realized with such a program as described above using an arithmetic processing unit.

Such program can be recorded in advance on, for example, a HDD as a recording medium built in an apparatus such as a remote controller 3 or computer apparatus, or a ROM in a microcomputer having a CPU.

Alternatively, the program can be stored or recorded temporarily or permanently on a removable recording medium such as a flexible disc, CD-ROM, MO (Magneto-Optical) disc, DVD, Blu-ray disc, magnetic disc, semiconductor memory or memory card. Such a removable recording medium can be provided as package software.

Other than installing from a removable recording medium into a personal computer, such program can be downloaded from a download site through a network such as a LAN (Local Area Network) or the Internet.

Further, such program is suitable for providing the controlling terminal apparatus of the embodiment in a wide range of uses. For example, by downloading the program into a portable information processing apparatus, a portable telephone set or the like, the apparatus such as a portable information processing apparatus can serve as the controlling terminal apparatus according to the embodiment of the present disclosure.

It is to be noted that the present technology can take such configurations as given below:

(1) A controlling terminal apparatus including:

a transmission section configured to transmit and output a control signal to a plurality of sound outputting apparatus;

a display section;

an operation detection section configured to detect an operation for the displayed substance of the display section; and

a control section configured to control the display section to display, for each of the sound outputting apparatus, an individual sound volume setting region showing a sound volume setting and including an operation element which can be operated to vary the sound volume setting, and a master sound volume setting region including an operation element which can be operated to vary the sound volume settings of the sound outputting apparatus at the same time,

the control section changing, when an operation for the master sound volume setting region is detected by the operation detection section, the sound volume setting of each of the individual sound volume setting regions using a value, which has a ratio equal to the ratio of the detected operation amount to an operable amount of the master sound volume setting region upon the operation, with respect to an operable amount of each of the individual sound volume setting regions, generating control signals indicative of the new sound volume settings, and controlling the transmission section to transmit and output the control signals.

(2) The controlling terminal apparatus according to (1),

wherein the control section carries out control differently between a sound volume balance maintaining state and a sound volume balance non-maintaining state of the sound outputting apparatus in response to the operation for the master sound volume setting region such that,

in the sound volume balance maintaining state, when an operation for the master sound volume setting region is detected, the value corresponding to the detected operation amount itself is used to change the sound volume setting of each of the individual sound volume setting regions and control signals for the instruction of the new sound volume settings are generated and then transmitted and outputted from the transmission section, but

in the sound volume balance non-maintaining state, when an operation for the master sound volume setting region is detected, the sound volume setting of each of the individual sound volume setting regions is changed using a value, which has a ratio equal to the ratio of the detected operation amount to an operable amount of the master sound volume setting region upon the operation, with respect to an operable amount of each of the individual sound volume setting regions, and control signals indicative of the new sound volume settings are generated and then transmitted and outputted from the transmission section.

(3) The controlling terminal apparatus according to (2),

wherein the control section

carries out control in the sound volume balance maintaining state when the sound volume settings of all of the individual sound volume setting regions are different from a condition of an end point of a sound volume setting variation range, but

transits from the sound volume balance maintaining state to the sound volume balance non-maintaining state when it is detected that, after the sound volume setting of one of the individual sound volume setting region comes to the state of the end point, the operation for the master sound volume setting region is carried out in the operation direction in which the sound volume setting of the one individual sound volume setting region has come to the end point.

(4) The controlling terminal apparatus according to (3), wherein the control section stores, upon the transition from the sound volume balance maintaining state to the sound volume balance non-maintaining state, the set value of the master sound volume setting region and the sound volume setting values of the individual sound volume setting regions upon the transition as control change point information.

(5) The controlling terminal apparatus according to (4), wherein, when the control section detects that, after the sound volume settings in the individual sound volume setting regions return to the sound volume setting values stored as the control change point information, an operation for the master sound volume setting region is carried out in the operation direction in which the sound volume settings have returned by the control in the sound volume balance non-maintaining state, the control section transits from the sound volume balance non-maintaining state to the sound volume balance maintaining state.

(6) The controlling terminal apparatus according to (4) or (5), wherein, when, in the sound volume balance non-maintaining state, an operation for one of the individual sound volume setting regions other than that one individual sound volume setting region whose sound volume setting has come to the end point is detected by the operation detection section, the control section updates the control change point information.

(7) The controlling terminal apparatus according to any one of (4) to (6), wherein, when, in the sound volume balance non-maintaining state, an operation for the one individual sound volume setting region whose sound volume setting has come to the end point is detected, the control section erases the control change point information stored therein and then transits to the sound volume balance maintaining state.

(8) The controlling terminal apparatus according to any one of (4) to (7), further including

a reception section configured to receive information from the plural sound outputting apparatus,

wherein the control section

changes, when information of a sound volume setting change is received from any of the sound outputting apparatus by the reception section, the sound volume setting in the individual sound volume setting region corresponding to the sound outputting apparatus from which the information is received, but

updates, when, in the sound volume balance non-maintaining state, the sound volume setting of one of the individual sound volume setting regions other than the one individual sound volume setting region whose sound volume setting has come to the end point is changed in response to the received information, the sound volume setting values relating to the individual sound volume setting region stored as the control change point information in response to the change of the sound volume setting.

(9) The controlling terminal apparatus according to any one of (4) to (8), further including

a reception section configured to receive information from the plural sound outputting apparatus,

wherein the control section

changes, when information of a sound volume setting change is received from any of the sound outputting apparatus by the reception section, the sound volume setting in the individual sound volume setting region corresponding to the sound outputting apparatus from which the information is received, but

erases, when, in the sound volume balance non-maintaining state, the sound volume setting of the one individual sound volume setting region whose sound volume setting has come to the end point is changed in response to the received information, the control change point information stored therein and then transits to the sound volume balance maintaining state.

(10) The controlling terminal apparatus according to any one of (2) to (9), wherein the control section controls the display section to execute display of display forms which are different between the sound volume balance maintaining state and the sound volume balance non-maintaining state.

(11) The controlling terminal apparatus according to any one of (2) to (10), wherein the control section controls the display section to display, in the sound volume balance maintaining state, an operation range of the master sound volume setting region within which a sound volume balance between the sound outputting apparatus can be maintained.

(12) The controlling terminal apparatus according to any one of (1) to (11),

wherein the plural sound outputting apparatus are connected to a network including an audio source apparatus and reproduces and outputs audio content distributed commonly from the audio source apparatus, and

the transmission section transmits and outputs a control signal to each of the sound outputting apparatus by communication through the network.

The present disclosure contains subject matter related to that disclosed in Japanese Priority Patent Application JP 2011-248247 filed in the Japan Patent Office on Nov. 14, 2011, the entire content of which is hereby incorporated by reference.

It should be understood by those skilled in the art that various modifications, combinations, sub-combinations and alterations may occur depending on design requirements and other factors insofar as they are within the scope of the appended claims or the equivalents thereof.

What is claimed is:

1. A controlling terminal apparatus, comprising:
a transmission section configured to transmit and output a control signal to a plurality of sound outputting apparatus;
a display section;
an operation detection section configured to detect an operation for the displayed substance of the display section; and
a control section configured to control the display section to display, for each of the sound outputting apparatus, an individual sound volume setting region showing a sound volume setting and including an operation element which can be operated to vary the sound volume setting, and a master sound volume setting region including an operation element which can be operated to vary the sound volume settings of the sound outputting apparatus at the same time,
the control section changing, when an operation for the master sound volume setting region is detected by the operation detection section, the sound volume setting of each of the individual sound volume setting regions using a value, which has a ratio equal to the ratio of the detected operation amount to an operable amount of the master sound volume setting region upon the operation, with respect to an operable amount of each of the individual sound volume setting regions, generating control signals indicative of the new sound volume settings, and controlling the transmission section to transmit and output the control signals.

2. The controlling terminal apparatus according to claim 1,
wherein the control section carries out control differently between a sound volume balance maintaining state and a sound volume balance non-maintaining state of the sound outputting apparatus in response to the operation for the master sound volume setting region such that,
in the sound volume balance maintaining state, when an operation for the master sound volume setting region is detected, the value corresponding to the detected operation amount itself is used to change the sound volume setting of each of the individual sound volume setting regions and control signals for the instruction of the new sound volume settings are generated and then transmitted and outputted from the transmission section, but
in the sound volume balance non-maintaining state, when an operation for the master sound volume setting region is detected, the sound volume setting of each of the individual sound volume setting regions is changed using a value, which has a ratio equal to the ratio of the detected operation amount to an operable amount of the master sound volume setting region upon the operation, with respect to an operable amount of each of the individual sound volume setting regions, and control signals indicative of the new sound volume settings are generated and then transmitted and outputted from the transmission section.

3. The controlling terminal apparatus according to claim 2,
wherein the control section
carries out control in the sound volume balance maintaining state when the sound volume settings of all of the individual sound volume setting regions are different from a condition of an end point of a sound volume setting variation range, but
transits from the sound volume balance maintaining state to the sound volume balance non-maintaining state when it is detected that, after the sound volume setting of one of the individual sound volume setting region comes to the state of the end point, the operation for the master sound volume setting region is carried out in the operation direction in which the sound volume setting of the one individual sound volume setting region has come to the end point.

4. The controlling terminal apparatus according to claim 3, wherein the control section stores, upon the transition from the sound volume balance maintaining state to the sound volume balance non-maintaining state, the set value of the master sound volume setting region and the sound volume setting values of the individual sound volume setting regions upon the transition as control change point information.

5. The controlling terminal apparatus according to claim 4, wherein, when the control section detects that, after the sound volume settings in the individual sound volume setting regions return to the sound volume setting values stored as the control change point information, an operation for the master sound volume setting region is carried out in the operation direction in which the sound volume settings have returned by the control in the sound volume balance non-maintaining state, the control section transits from the sound volume balance non-maintaining state to the sound volume balance maintaining state.

6. The controlling terminal apparatus according to claim 4, wherein, when, in the sound volume balance non-maintaining state, an operation for one of the individual sound volume setting regions other than that one individual sound volume setting region whose sound volume setting has come to the end point is detected by the operation detection section, the control section updates the control change point information.

7. The controlling terminal apparatus according to claim 4, wherein, when, in the sound volume balance non-maintaining state, an operation for the one individual sound volume setting region whose sound volume setting has come to the end point is detected, the control section erases the control change point information stored therein and then transits to the sound volume balance maintaining state.

8. The controlling terminal apparatus according to claim 4, further comprising
a reception section configured to receive information from the plural sound outputting apparatus,
wherein the control section
changes, when information of a sound volume setting change is received from any of the sound outputting apparatus by the reception section, the sound volume setting in the individual sound volume setting region corresponding to the sound outputting apparatus from which the information is received, but
updates, when, in the sound volume balance non-maintaining state, the sound volume setting of one of the individual sound volume setting regions other than the one individual sound volume setting region whose sound volume setting has come to the end point is changed in response to the received information, the sound volume setting values relating to the individual sound volume setting region stored as the control change point information in response to the change of the sound volume setting.

9. The controlling terminal apparatus according to claim 4, further comprising
a reception section configured to receive information from the plural sound outputting apparatus,
wherein the control section
changes, when information of a sound volume setting change is received from any of the sound outputting apparatus by the reception section, the sound volume setting in the individual sound volume setting region corresponding to the sound outputting apparatus from which the information is received, but
erases, when, in the sound volume balance non-maintaining state, the sound volume setting of the one individual sound volume setting region whose sound volume setting has come to the end point is changed in response to the received information, the control change point information stored therein and then transits to the sound volume balance maintaining state.

10. The controlling terminal apparatus according to claim 2, wherein the control section controls the display section to execute display of display forms which are different between the sound volume balance maintaining state and the sound volume balance non-maintaining state.

11. The controlling terminal apparatus according to claim 2, wherein the control section controls the display section to display, in the sound volume balance maintaining state, an operation range of the master sound volume setting region within which a sound volume balance between the sound outputting apparatus can be maintained.

12. The controlling terminal apparatus according to claim 1,
wherein the plural sound outputting apparatus are connected to a network including an audio source apparatus and reproduces and outputs audio content distributed commonly from the audio source apparatus, and
the transmission section transmits and outputs a control signal to each of the sound outputting apparatus by communication through the network.

13. A control method performed by a controlling terminal apparatus which includes a transmission section configured to transmit and output a control signal to a plurality of sound outputting apparatus, a display section, and an operation detection section configured to detect an operation for the displayed substance of the display section, the method comprising:
controlling the display section to display, for each of the sound outputting apparatus, an individual sound volume setting region showing a sound volume setting and including an operation element which can be operated to vary the sound volume setting, and a master sound volume setting region including an operation element which can be operated to vary the sound volume settings of the sound outputting apparatus at the same time;
changing, when an operation for the master sound volume setting region is detected by the operation detection section, the sound volume setting of each of the individual sound volume setting regions using a value, which has a ratio equal to the ratio of the detected operation amount to an operable amount of the master sound volume setting region upon the operation, with respect to an operable amount of each of the individual sound volume setting regions; and
generating control signals indicative of the changed new sound volume settings and controlling the transmission section to transmit and output the control signals.

14. A program which causes an arithmetic operation processing apparatus of a controlling terminal apparatus which includes a transmission section configured to transmit and output a control signal to a plurality of sound outputting apparatus, a display section, and an operation detection section configured to detect an operation for the displayed substance of the display section, to execute processing of:
controlling the display section to display, for each of the sound outputting apparatus, an individual sound volume setting region showing a sound volume setting and including an operation element which can be operated to vary the sound volume setting, and a master sound volume setting region including an operation element which can be operated to vary the sound volume settings of the sound outputting apparatus at the same time;
changing, when an operation for the master sound volume setting region is detected by the operation detection section, the sound volume setting of each of the individual sound volume setting regions using a value, which has a ratio equal to the ratio of the detected operation amount to an operable amount of the master sound volume setting region upon the operation, with respect to an operable amount of each of the individual sound volume setting regions; and
generating control signals indicative of the changed new sound volume settings and controlling the transmission section to transmit the control signals.
